(19) United States
(12) Patent Application Publication
(10) Pub. No.: US 2026/0168095 A1
(43) Pub. Date: Jun. 18, 2026

(54) PHOSPHONIUM YLIDE COMPLEXES AS PRECURSORS FOR THIN LAYERS CONTAINING A METAL ELEMENT

(71) Applicant: ASM IP Holding B.V., Almere (NL)

(72) Inventors: Charles Dezelah, Helsinki (FI); Jan Willem Maes, Wilrijk (BE); Qi Xie, Shanghai (CN)

(21) Appl. No.: 19/414,570

(22) Filed: Dec. 10, 2025

Related U.S. Application Data
(60) Provisional application No. 63/734,087, filed on Dec. 14, 2024.

(51) Int. Cl. C23C 16/455; C23C 16/52

(52) U.S. Cl. CPC C23C 16/45553; C23C 16/45544; C23C 16/52

(57) ABSTRACT

Disclosed herein is a method and a system for forming a metal-containing layer on a semiconductor substrate using a metal precursor that comprises a phosphonium ylide ligand. Also disclosed is a composition comprising the metal precursor and semiconductor device structure that comprises the metal-containing layer.

### CROSS-REFERENCE TO RELATED APPLICATIONS

This application claims priority to U.S. Provisional Patent Application Ser. No. 63/734,087 filed Dec. 14, 2024 titled PHOSPHONIUM YLIDE COMPLEXES AS PRECURSORS FOR THIN LAYERS CONTAINING A METAL ELEMENT, the disclosure of which is hereby incorporated by reference in its entirety.

### FIELD OF INVENTION

The present disclosure generally relates to the field of semiconductor devices. More particularly, it relates to a method for forming a metal-containing layer on a semiconductor substrate, related devices and apparatus for producing the same.

### BACKGROUND OF THE DISCLOSURE

At present, the selection of atomic layer deposition (ALD) and chemical vapour deposition (CVD) precursors for the growth of films containing certain metallic elements is restricted to those containing only a few types of ligands, such as Cp, amdinates, beta-diketonates, dialkylamides, alkoxides, alkyls, and so on. The known examples have limitations that make them less than ideal for the growth of desired layers (films). Limitations include a limited (and often insufficient) range of reactivity, low volatility for Cp and diketonate complexes, or low thermal stability in the case of amdinates, dialkylamido, alkoxide, and alkyl precursors, and low activation energy decomposition pathways that lead to impurities and high electrical resistivity. These drawbacks make the current chemistry options sub-optimal choices for film growth for many applications. In particular, the reactivity of currently available ligands makes materials such as binary metal borides, carbides, and nitrides difficult to achieve.

In view of the above, a need exists to provide alternatives for precursors for thin layers containing metal elements that are capable of overcoming some of these drawbacks.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In general, the technology disclosed herein relates to the field of semiconductor devices, and more particularly to a method for forming a metal-containing layer on a semiconductor substrate using a novel metal precursor that comprises a phosphonium ylide ligand; the metal precursor also comprises a metal element. The precursor may contain other common ligands in addition to the phosphonium ylide. The metal deposition may be in the form of oxides, nitrides, carbides, borides, sulfides, phosphides and the like. This method is applicable to the manufacture of semiconductor devices.

The precursors according to the present invention possess one or more anionic carbon atoms bonded to a metal atom; this carbon-metal bond is highly reactive towards many types of protonolysis reactions, allowing for a wide range of binary metal/non-metal materials to be readily accessible, e.g., oxides, nitrides, carbides, sulfides, borides, phosphides, and the like. Accordingly, the precursors according to the present invention have improved reactivity compared to current best-known methods, and also provide improvements in thermal stability, volatility, and ability to access difficult materials such as carbides, borides, and nitrides, which makes their use in methods and apparatus for forming metal-coating layers on semiconductor substrates very advantageous.

The benefits of using the precursors according to the invention relative to existing precursors are as follows:
1) The precursors of the invention offer a direct route to metal carbides, which have expected applications for back-end-of-line (BEOL) barrier/liner layers, as current methods often do not provide carbon in a purely carbidic form.

2) The precursors of the invention constitute an alternative method for oxides and sulfides, providing higher thermal stability and potentially improved reactivity for these materials.

3) The precursors of the invention provide a potential route to borides using diborane, triethylboron, boron trihalide, or other boron containing co-reactants. Metal borides are challenging compounds to subject to deposition by ALD, and very few methods to obtain them are available.

4) The precursors of the invention provide a possible route to nitrides, using NH₃, hydrazine, or alkylhydrazine as a co-reactant. Although known methods exist for these thin layers, the method according to the present invention allows for better thermal stability and low resistivity metal-containing layers for BEOL applications.

5) The precursors of the invention also provide a new method for producing metal-containing layers when the precursor is combined with a suitable reducing agent, e.g., H₂, formic acid, formaldehyde, disilane, or others. Metal-containing layers of metals according to the invention, such as molybdenum and tungsten have wide current, very advantageous for uses such as conductors in logic and memory devices. Often it is difficult to achieve these metal-containing layers with low impurity levels without the use of plasma or metal halides, since thermal metalorganic approaches introduce unacceptable levels of nitrogen and carbon impurities; accordingly the method according to the present invention allows to obtain metal-containing layers with low impurity levels.

Compounds containing this ligand possess one or more anionic carbon atoms bonded to a metal atom. It is expected that this carbon-metal bond is highly reactive towards many types of protonolysis reactions, allowing for a wide range of binary metal/non-metal materials to be readily accessible, e.g., oxides, nitrides, carbides, sulfides, borides, phosphides, and the like. It is also expected that with a suitable co-reactant, a metal-containing layer can be formed. Additionally, it is anticipated that a co-reactant and conditions can be found where the reaction of the precursor would generate a volatile phosphine or phosphine oxide as a by-product, such that one of the phosphorus-carbon bonds breaks, enabling the formation of metal carbide layers.

Accordingly, an aspect of the present disclosure relates to an apparatus comprising:
a reaction chamber constructed and arranged to hold at least a semiconductor substrate;
a metal precursor source constructed and arranged to provide a vapor of at least one metal precursor;
a precursor distribution and removal system configured to provide the vapor of the metal precursor from the metal precursor source to the reaction chamber and to remove the vapor of the metal precursor from the reaction chamber; and
a sequence controller operably connected to the precursor distribution system and removal system, and comprising a memory provided with a program configured to control the flow of the metal precursor from the metal precursor source to the reaction chamber by activating the precursor distribution and removal system during one or more cycles; whereby, as a result of the cycles, a metal-containing layer is formed on the semiconductor substrate in the reaction chamber;
   wherein the at least one metal precursor comprises:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
at least one ligand of formula (I):

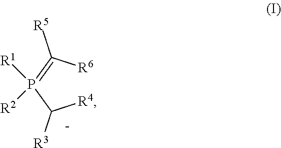

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.

In particular embodiments, the apparatus as disclosed herein further comprising a reactant source constructed and arranged to provide a vapor of a reactant; wherein the precursor distribution and removal system is further configured to provide the vapor of the reactant from the reactant source to the reaction chamber; wherein the program stored in the memory is further configured to control the flow of the reactant from the reactant source to the reaction chamber during the one or more cycles.

In some embodiments, the at least one reactant is selected from the group comprising oxide reactants, nitride reactants, boride reactants, reducing agents, phosphide reactants, carbide reactants, sulfide reactants, and combinations thereof.

Another aspect of the present disclosure relates to a method for forming a metal-containing layer on a semiconductor substrate, comprising the steps of:
a) providing a semiconductor substrate into a reaction chamber;
b) executing one or more cycles, each cycle comprising:
a metal precursor pulse, wherein at least a part of the semiconductor substrate is contacted by at least one metal precursor by introducing the at least one metal precursor into the reaction chamber;
wherein the at least one metal precursor comprises:
   at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
   at least one ligand of formula (I):

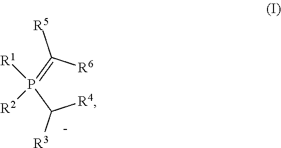

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl,
whereby, as a result of the cycles, the metal-containing layer is formed on the semiconductor substrate in the reaction chamber.

In some embodiments, the at least one cycle further comprises a reactant pulse, wherein at least a part of the semiconductor substrate is contacted by at least one reactant, by introducing the at least one reactant into the reaction chamber; wherein the at least one reactant is selected from the group comprising oxide reactants, nitride reactants, boride reactants, reducing agents, phosphide reactants, carbide reactants, sulfide reactants, and combinations thereof.

Another aspect of the present disclosure relates to a semiconductor device structure. The semiconductor device structure according to the present invention comprises a metal-containing layer formed according to a method disclosed herein above.

Yet another aspect of the present disclosure relates to a composition configured for forming a metal containing film, the composition comprising a metal precursor as disclosed herein.

Yet another aspect of the present disclosure relates to a vessel comprising a composition configured for forming a metal containing film, the vessel comprising a composition comprising a metal precursor as disclosed herein.

An overview of various other aspects of the technology of the present disclosure is provided herein below, followed by a detailed description of specific embodiments. It should be understood that the objectives and advantages mentioned above apply equally to the various other aspects and features as disclosed herein.

### DESCRIPTION OF THE FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 schematically illustrates an exemplary embodiment of a method (100) for forming a metal layer on a semiconductor substrate as disclosed herein.

FIG. 2 schematically illustrates an apparatus (600) in accordance with yet additional exemplary embodiments of the disclosure.

### DETAILED DESCRIPTION OF EXEMPLARY EMBODIMENTS

Although certain embodiments and examples are disclosed below, it will be understood by those in the art that the present disclosure extends beyond the specifically disclosed embodiments and/or uses of the present disclosure and obvious modifications and equivalents thereof. Thus, it is intended that the scope of the present disclosure should not be limited by the particular disclosed embodiments described below.

In the following detailed description, the technology underlying the present disclosure will be described by means of different aspects thereof. It will be readily understood that the aspects of the present disclosure, as generally described herein, and illustrated in the figures, can be arranged, substituted, combined, and designed in a wide variety of different configurations, all of which are explicitly contemplated and form part of this disclosure. This description is meant to aid the reader in understanding the technological concepts more easily, but it is not meant to limit the scope of the present disclosure, which is limited only by the claims. Hence, the description below is to be regarded as illustrative in nature, and not as restrictive.

Reference throughout this specification to “one embodiment” or “an embodiment” means that a particular feature, structure, or characteristic described in connection with the embodiment is included in at least one embodiment of the present disclosure. Thus, appearances of the phrases “in one embodiment” or “in an embodiment” in various places throughout this specification are not necessarily all referring to the same embodiment.

As used herein, the terms “comprising”, “comprises” and “comprised of” are synonymous with “including”, “includes” or “containing”, “contains”, and are inclusive or open-ended and do not exclude additional, non-recited members, elements, or method steps. The terms “comprising”, “comprises” and “comprised of” when referring to recited members, elements, or method steps also include embodiments which “consist of” the recited members, elements or method steps.

The singular forms “a”, “an”, and “the” include both singular and plural referents unless the context clearly dictates otherwise.

Objects described herein as being “connected” or “coupled” reflect a functional relationship between the described objects, that is, the terms indicate the described objects must be connected in a way to perform a designated function which may be a direct or indirect connection in an electrical or nonelectrical (i.e., physical) manner, as appropriate for the context in which the term is used.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result.

As used herein, the term “about” is used to provide flexibility to a numerical value or range endpoint by providing that a given value may be “a little above” or “a little below” the value or endpoint, depending on the specific context. Unless otherwise stated, use of the term “about” in accordance with a specific number or numerical range should also be understood to provide support for such numerical terms or range without the term “about”. For example, the recitation of “about 30” should be construed as not only providing support for values a little above and a little below 30, but also for the actual numerical value of 30 as well.

The recitation of numerical ranges by endpoints includes all integer numbers and, where appropriate, fractions subsumed within that range (e.g., 1 to 5 can include 1, 2, 3, 4 when referring to, for example, a number of elements, and can also include 1.5, 2, 2.75 and 3.80, when referring to, for example, measurements). This applies to numerical ranges irrespective of whether they are introduced by the expression “from . . . to . . . ” or the expression “between . . . and . . . ” or another expression. The recitation of endpoints also include the endpoint values themselves (e.g., from 1.0 to 5.0 includes both 1.0 and 5.0). Any numerical range recited herein is intended to include all sub-ranges subsumed therein. Furthermore, the terms first, second, third and the like in the description and in the claims, are used for distinguishing between similar elements and not necessarily for describing a sequential or chronological order, unless specified. It is to be understood that the terms so used are interchangeable under appropriate circumstances and that the embodiments of the disclosure described herein are capable of operation in other sequences than described or illustrated herein.

Reference in this specification may be made to devices, structures, apparatus, systems, or methods that provide “improved” performance (e.g., increased or decreased results, depending on the context). It is to be understood that unless otherwise stated, such “improvement” is a measure of a benefit obtained based on a comparison to devices, structures, apparatus, systems or methods in the prior art. Furthermore, it is to be understood that the degree of improved performance may vary between disclosed embodiments and that no equality or consistency in the amount, degree, or realization of improved performance is to be assumed as universally applicable.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas.

In some cases, the term “precursor” can refer to a compound that participates in the chemical reaction that produces another compound, particularly a compound that constitutes a metal-containing layer matrix or a main skeleton of a metal-containing layer.

In the present description, technology is described that relates to a method and apparatus for manufacturing a metal-containing layer on a semiconductor substrate. The present inventors have surprisingly observed that a precursor comprising a phosphonium ylide ligand and a metal element can be readily used for forming metal-containing layers on semiconductor substrates. Advantageously, the precursors according to the present description are highly reactive towards many types of protonolysis reactions, allowing for a wide range of binary metal/non-metal materials to be readily accessible for the forming of metal-containing layers on semiconductor substrates.

Accordingly, one aspect of the present disclosure relates to an apparatus comprising:
a reaction chamber constructed and arranged to hold at least a semiconductor substrate;
a metal precursor source constructed and arranged to provide a vapor of at least one metal precursor;
a precursor distribution and removal system configured to provide the vapor of the metal precursor from the metal precursor source to the reaction chamber and to remove the vapor of the metal precursor from the reaction chamber; and
a sequence controller operably connected to the precursor distribution system and removal system, and comprising a memory provided with a program configured to control the flow of the metal precursor from the metal precursor source to the reaction chamber by activating the precursor distribution and removal system during one or more cycles; whereby, as a result of the cycles, a metal-containing layer is formed on the semiconductor substrate in the reaction chamber;
wherein the at least one metal precursor comprises:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
at least one ligand of formula (I):

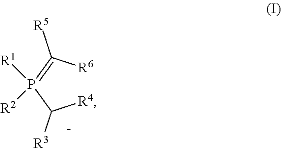

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.

As used herein, the term “substrate” can refer to any underlying material or materials that can be used to form, or upon which, a device, a circuit, or a metal-containing layer (film) can be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. A substrate can comprise a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate.

Examples of suitable substrates include wafers, such as silicon, silica, glass, or GaAs wafers. The wafer may have one or more layers of differing materials deposited on it from a previous manufacturing step. For example, the wafers may include silicon layers (crystalline, amorphous, porous, etc.), silicon oxide layers, silicon nitride layers, silicon oxy nitride layers, carbon doped silicon oxide (SiCOH) layers, or combinations thereof. Additionally, the wafers may include copper layers or noble metal layers (e.g., platinum, palladium, rhodium, or gold). The wafers may include barrier layers, such as manganese, manganese oxide, etc. Plastic layers, such as poly(3,4-ethylenedioxythiophene)poly (styrenesulfonate) may also be used. The layers may be planar or patterned.

In particular embodiments, the substrate may comprise silicon, silicon germanium, silicon oxide, gallium arsenide, gallium nitride, or silicon carbide (as the bulk semiconductor material).

A “film” or “layer” as used herein interchangeably refers to a material extending in a direction perpendicular to a thickness direction to cover an entire target or concerned surface, or simply a layer covering a target or concerned surface. In particular embodiments, a film or layer refers to a structure having a certain thickness formed on a surface or a synonym of film or a non-film structure. A layer can encompass a continuous or non-continuous structure or material, such as material deposited according to the present technology. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers.

For example, a film and/or layer can include two-dimensional materials, three-dimensional materials, nanoparticles or even partial or full molecular layers or partial or full atomic layers or clusters of atoms and/or molecules, or layers consisting of isolated atoms and/or molecules. A film or layer may comprise material or a layer with pinholes, which may be continuous or non-continuous.

Reference throughout this specification to substituents is meant to indicate that one or more hydrogen atoms on the atom indicated in the expression using “substituted” is replaced with a selection from an indicated group as detailed below, provided that the indicated atom's normal valence is not exceeded, and that the substitution results in a chemically stable compound, i.e. a compound that is sufficiently robust to survive isolation from a reaction mixture.

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C₁₋₁₀alkyl”, as a group or part of a group, refers to a hydrocarbyl group of formula —CₙH₂ₙ₊₁ wherein n is a number ranging from 1 to 10. Thus, for example, “C₁₋₈alkyl” includes all linear or branched alkyl groups with between 1 and 8 carbon atoms, and thus includes methyl (“Me”), ethyl (“Et”), n-propyl (“nPr”), i-propyl (“iPr”), butyl and its isomers (e.g., n-butyl, i-butyl and t-butyl); pentyl and its isomers, hexyl and its isomers, etc. A “substituted alkyl” refers to an alkyl group substituted with one or more substituent(s) (for example 1 to 3 substituent(s), for example 1, 2, or 3 substituent(s) at any available point of attachment.

The term “C₁₋₆alkoxy”, as a group or part of a group, refers to a group having the formula —OR wherein R is C₁₋₆alkyl as defined herein above. Non-limiting examples of suitable C₁₋₆alkoxy include methoxy, ethoxy, propoxy, isopropoxy, butoxy, isobutoxy, sec-butoxy, tert-butoxy, pentyloxy and hexyloxy.

The term “cycloalkyl”, as a group or part of a group, refers to a cyclic alkyl group, that is a monovalent, saturated, hydrocarbyl group having 1 or more cyclic structure, and comprising from 3 to 10 carbon atoms, more preferably from 3 to 8 carbon atoms; more preferably from 3 to 6 carbon atoms. Cycloalkyl includes all saturated hydrocarbon groups containing 1 or more rings, including monocyclic, bicyclic groups or tricyclic. The further rings of multi-ring cycloalkyls may be either fused, bridged and/or joined through one or more spiro atoms. When a subscript is used herein following a carbon atom, the subscript refers to the number of carbon atoms that the named group may contain. For example, the term “C₃₋₁₀cycloalkyl”, a cyclic alkyl group comprising from 3 to 10 carbon atoms. For example, the term “C₃₋₈cycloalkyl”, a cyclic alkyl group comprising from 3 to 8 carbon atoms. For example, the term “C₃₋₆cycloalkyl”, a cyclic alkyl group comprising from 3 to 6 carbon atoms. Examples of C₃₋₁₀cycloalkyl groups include but are not limited to adamantyl, cyclopropyl, cyclobutyl, cyclopentyl, cyclohexyl, cycloheptyl, cyclooctyl, bicycle[2.2.1]heptan-2yl, (1S,4R)-norbornan-2-yl, (1R,4R)-norbornan-2-yl, (1S,4S)-norbornan-2-yl, (1R,4S)-norbornan-2-yl.

The term “aryl”, as a group or part of a group, refers to a polyunsaturated, aromatic hydrocarbyl group having a single ring (i.e. phenyl) or multiple aromatic rings fused together (e.g., naphthyl), or linked covalently, typically containing 6 to 12 carbon atoms, wherein at least one ring is aromatic. The aromatic ring may optionally include one to two additional rings (either cycloalkyl, heterocyclyl or heteroaryl) fused thereto. Examples of suitable aryl include C₆₋₁₀aryl, more preferably C₆₋₈aryl. Non-limiting examples of aryl comprise phenyl, biphenylyl, biphenylenyl, or 1- or 2-naphthalenyl; 1-, 2-, 3-, 4-, 5- or 6-tetralinyl (also known as “1,2,3,4-tetrahydronaphtalene); 1-, 2-, 3-, 4-, 5-, 6-, 7- or 8-azulenyl, 4-, 5-, 6 or 7-indenyl; 4- or 5-indanyl; 5-, 6-, 7- or 8-tetrahydronaphthyl; 1,2,3,4-tetrahydronaphthyl; and 1,4-dihydronaphthyl; 1-, 2-, 3-, 4- or 5-pyrenyl. A “substituted aryl” refers to an aryl group having one or more substituent(s) (for example 1, 2 or 3 substituent(s), or 1 to 2 substituent(s)), at any available point of attachment.

The terms “heterocyclyl” or “heterocycloakyl” or “heterocyclo”, as a group or part of a group, refer to non-aromatic, fully saturated or partially unsaturated cyclic groups (for example, 3 to 7 member monocyclic, 7 to 11 member bicyclic, or comprising a total of 3 to 10 ring atoms) which have at least one heteroatom in at least one carbon atom-containing ring; wherein said ring may be fused to an aryl, cycloalkyl, heteroaryl or heterocyclyl ring. Each ring of the heterocyclyl group containing a heteroatom may have 1, 2, 3 or 4 heteroatoms selected from N, O, and/or S, where the N and S heteroatoms may optionally be oxidized and the N heteroatoms may optionally be quaternized; and wherein at least one carbon atom of heterocyclyl can be oxidized to form at least one C═O. The heterocyclic group may be attached at any heteroatom or carbon atom of the ring or ring system, where valence allows. The rings of multi-ring heterocycles may be fused, bridged and/or joined through one or more spiro atoms.

Non limiting exemplary heterocyclic groups include aziridinyl, oxiranyl, thiiranyl, piperidinyl, azetidinyl, oxetanyl, pyrrolidinyl, thietanyl, 2-imidazolinyl, pyrazolidinyl, imidazolidinyl, isoxazolinyl, oxazolidinyl, isoxazolidinyl, thiazolidinyl, isothiazolidinyl, succinimidyl, 3H-indolyl, indolinyl, isoindolinyl, chromanyl (also known as 3,4-dihydrobenzo[b]pyranyl), 2H-pyrrolyl, 1-pyrrolinyl, 2-pyrrolinyl, 3-pyrrolinyl, 4H-quinolizinyl, 2-oxopiperazinyl, piperazinyl, homopiperazinyl, 2-pyrazolinyl, 3-pyrazolinyl, tetrahydro-2H-pyranyl, 2H-pyranyl, 4H-pyranyl, 3,4-dihydro-2H-pyranyl, 3-dioxolanyl, 1,4-dioxanyl, 2,5-dioximidazolidinyl, 2-oxopiperidinyl, 2-oxopyrrolodinyl, tetrahydropyranyl, tetrahydrofuranyl, tetrahydrothiophenyl, tetrahydroquinolinyl, tetrahydroisoquinolin-1-yl, tetrahydroisoquinolin-2-yl, tetrahydroisoquinolin-3-yl, tetrahydroisoquinolin-4-yl, thiomorpholin-4-yl, thiomorpholin-4-ylsulfoxide, thiomorpholin-4-ylsulfone, 1,3-dioxolanyl, 1,4-oxathianyl, 1,4-dithianyl, 1,3,5-trioxanyl, 1H-pyrrolizinyl, tetrahydro-1,1-dioxothiophenyl, N-formylpiperazinyl, and morpholin-4-yl. The term “aziridinyl” as used herein includes aziridin-1-yl and aziridin-2-yl. The term “oxyranyl” as used herein includes oxiranyl-2-yl. The term “thiiranyl” as used herein includes thiiran-2-yl. The term “azetidinyl” as used herein includes azetidin-1-yl, azetidin-2-yl, and azetidin-3-yl. The term “oxetanyl” as used herein includes oxetan-2-yl and oxetan-3-yl. The term “thietanyl” as used herein includes thietan-2-yl and thietan-3-yl. The term “pyrrolidinyl” as used herein includes pyrrolidin-1-yl, pyrrolidin-2-yl and pyrrolidin-3-yl. The term “tetrahydrofuranyl” as used herein includes tetrahydrofuran-2-yl and tetrahydrofuran-3-yl. The term “tetrahydrothiophenyl” as used herein includes tetrahydrothiophen-2-yl and tetrahydrothiophen-3-yl. The term “succinimidyl” as used herein includes succinimid-1-yl and succinimid-3-yl. The term “dihydropyrrolyl” as used herein includes 2,3-dihydropyrrol-1-yl, 2,3-dihydro-1H-pyrrol-2-yl, 2,3-dihydro-1H-pyrrol-3-yl, 2,5-dihydropyrrol-1-yl, 2,5-dihydro-1H-pyrrol-3-yl, and 2,5-dihydropyrrol-5-yl. The term “2H-pyrrolyl” as used herein includes 2H-pyrrol-2-yl, 2H-pyrrol-3-yl, 2H-pyrrol-4-yl, and 2H-pyrrol-5-yl. The term “3H-pyrrolyl” as used herein includes 3H-pyrrol-2-yl, 3H-pyrrol-3-yl, 3H-pyrrol-4-yl, and 3H-pyrrol-5-yl. The term “dihydrofuranyl” as used herein includes 2,3-dihydrofuran-2-yl, 2,3-dihydrofuran-3-yl, 2,3-dihydrofuran-4-yl, 2,3-dihydrofuran-5-yl, 2,5-dihydrofuran-2-yl, 2,5-dihydrofuran-3-yl, 2,5-dihydrofuran-4-yl and 2,5-dihydrofuran-5-yl. The term “dihydrothiophenyl” as used herein includes 2,3-dihydrothiophen-2-yl, 2,3-dihydrothiophen-3-yl, 2,3-dihydrothiophen-4-yl, 2,3-dihydrothiophen-5-yl, 2,5-dihydrothiophen-2-yl, 2,5-dihydrothiophen-3-yl, 2,5-dihydrothiophen-4-yl, and 2,5-dihydrothiophen-5-yl. The term “imidazolidinyl” as used herein includes imidazolidin-1-yl, imidazolidin-2-yl, and imidazolidin-4-yl. The term “pyrazolidinyl” as used herein includes pyrazolidin-1-yl, pyrazolidin-3-yl, and pyrazolidin-4-yl. The term “imidazolinyl” as used herein includes imidazolin-1-yl, imidazolin-2-yl, imidazolin-4-yl, and imidazolin-5-yl. The term “pyrazolinyl” as used herein includes 1-pyrazolin-3-yl, 1-pyrazolin-4-yl, 2-pyrazolin-1-yl, 2-pyrazolin-3-yl, 2-pyrazolin-4-yl, 2-pyrazolin-5-yl, 3-pyrazolin-1-yl, 3-pyrazolin-2-yl, 3-pyrazolin-3-yl, 3-pyrazolin-4-yl, and 3-pyrazolin-5-yl. The term “dioxolanyl” also known as “1,3-dioxolanyl” as used herein includes dioxolan-2-yl, dioxolan-4-yl, and dioxolan-5-yl. The term “dioxolyl” also known as “1,3-dioxolyl” as used herein includes dioxol-2-yl, dioxol-4-yl, and dioxol-5-yl. The term “oxazolidinyl” as used herein includes oxazolidin-2-yl, oxazolidin-3-yl, oxazolidin-4-yl, and oxazolidin-5-yl. The term “isoxazolidinyl” as used herein includes isoxazolidin-2-yl, isoxazolidin-3-yl, isoxazolidin-4-yl, and isoxazolidin-5-yl. The term “oxazolinyl” as used herein includes 2-oxazolinyl-2-yl, 2-oxazolinyl-4-yl, 2-oxazolinyl-5-yl, 3-oxazolinyl-2-yl, 3-oxazolinyl-4-yl, 3-oxazolinyl-5-yl, 4-oxazolinyl-2-yl, 4-oxazolinyl-3-yl, 4-oxazolinyl-4-yl, and 4-oxazolinyl-5-yl. The term “isoxazolinyl” as used herein includes 2-isoxazolinyl-3-yl, 2-isoxazolinyl-4-yl, 2-isoxazolinyl-5-yl, 3-isoxazolinyl-3-yl, 3-isoxazolinyl-4-yl, 3-isoxazolinyl-5-yl, 4-isoxazolinyl-2-yl, 4-isoxazolinyl-3-yl, 4-isoxazolinyl-4-yl, and 4-isoxazolinyl-5-yl. The term “thiazolidinyl” as used herein includes thiazolidin-2-yl, thiazolidin-3-yl, thiazolidin-4-yl, and thiazolidin-5-yl. The term “isothiazolidinyl” as used herein includes isothiazolidin-2-yl, isothiazolidin-3-yl, isothiazolidin-4-yl, and isothiazolidin-5-yl. The term “thiazolinyl” as used herein includes 2-thiazolinyl-2-yl, 2-thiazolinyl-4-yl, 2-thiazolinyl-5-yl, 3-thiazolinyl-2-yl, 3-thiazolinyl-4-yl, 3-thiazolinyl-5-yl, 4-thiazolinyl-2-yl, 4-thiazolinyl-3-yl, 4-thiazolinyl-4-yl, and 4-thiazolinyl-5-yl. The term “isothiazolinyl” as used herein includes 2-isothiazolinyl-3-yl, 2-isothiazolinyl-4-yl, 2-isothiazolinyl-5-yl, 3-isothiazolinyl-3-yl, 3-isothiazolinyl-4-yl, 3-isothiazolinyl-5-yl, 4-isothiazolinyl-2-yl, 4-isothiazolinyl-3-yl, 4-isothiazolinyl-4-yl, and 4-isothiazolinyl-5-yl. The term “piperidyl” also known as “piperidinyl” as used herein includes piperid-1-yl, piperid-2-yl, piperid-3-yl, and piperid-4-yl. The term “dihydropyridinyl” as used herein includes 1,2-dihydropyridin-1-yl, 1,2-dihydropyridin-2-yl, 1,2-dihydropyridin-3-yl, 1,2-dihydropyridin-4-yl, 1,2-dihydropyridin-5-yl, 1,2-dihydropyridin-6-yl, 1,4-dihydropyridin-1-yl, 1,4-dihydropyridin-2-yl, 1,4-dihydropyridin-3-yl, 1,4-dihydropyridin-4-yl, 2,3-dihydropyridin-2-yl, 2,3-dihydropyridin-3-yl, 2,3-dihydropyridin-4-yl, 2,3-dihydropyridin-5-yl, 2,3-dihydropyridin-6-yl, 2,5-dihydropyridin-2-yl, 2,5-dihydropyridin-3-yl, 2,5-dihydropyridin-4-yl, 2,5-dihydropyridin-5-yl, 2,5-dihydropyridin-6-yl, 3,4-dihydropyridin-2-yl, 3,4-dihydropyridin-3-yl, 3,4-dihydropyridin-4-yl, 3,4-dihydropyridin-5-yl, and 3,4-dihydropyridin-6-yl. The term “tetrahydropyridinyl” as used herein includes 1,2,3,4-tetrahydropyridin-1-yl, 1,2,3,4-tetrahydropyridin-2-yl, 1,2,3,4-tetrahydropyridin-3-yl, 1,2,3,4-tetrahydropyridin-4-yl, 1,2,3,4-tetrahydropyridin-5-yl, 1,2,3,4-tetrahydropyridin-6-yl, 1,2,3,6-tetrahydropyridin-1-yl, 1,2,3,6-tetrahydropyridin-2-yl, 1,2,3,6-tetrahydropyridin-3-yl, 1,2,3,6-tetrahydropyridin-4-yl, 1,2,3,6-tetrahydropyridin-5-yl, 1,2,3,6-tetrahydropyridin-6-yl, 2,3,4,5-tetrahydropyridin-2-yl, 2,3,4,5-tetrahydropyridin-3-yl, 2,3,4,5-tetrahydropyridin-4-yl, 2,3,4,5-tetrahydropyridin-5-yl, and 2,3,4,5-tetrahydropyridin-6-yl. The term “tetrahydropyranyl” also known as “oxanyl” or “tetrahydro-2H-pyranyl”, as used herein includes tetrahydropyran-2-yl, tetrahydropyran-3-yl, and tetrahydropyran-4-yl. The term “2H-pyranyl” as used herein includes 2H-pyran-2-yl, 2H-pyran-3-yl, 2H-pyran-4-yl, 2H-pyran-5-yl, and 2H-pyran-6-yl. The term “4H-pyranyl” as used herein includes 4H-pyran-2-yl, 4H-pyran-3-yl, and 4H-pyran-4-yl. The term “3,4-dihydro-2H-pyranyl” as used herein includes 3,4-dihydro-2H-pyran-2-yl, 3,4-dihydro-2H-pyran-3-yl, 3,4-dihydro-2H-pyran-4-yl, 3,4-dihydro-2H-pyran-5-yl, and 3,4-dihydro-2H-pyran-6-yl. The term “3,6-dihydro-2H-pyranyl” as used herein includes 3,6-dihydro-2H-pyran-2-yl, 3,6-dihydro-2H-pyran-3-yl, 3,6-dihydro-2H-pyran-4-yl, 3,6-dihydro-2H-pyran-5-yl, and 3,6-dihydro-2H-pyran-6-yl. The term “tetrahydrothiophenyl”, as used herein includes tetrahydrothiophen-2-yl, tetrahydrothiophenyl-3-yl, and tetrahydrothiophenyl-4-yl. The term “2H-thiopyranyl” as used herein includes 2H-thiopyran-2-yl, 2H-thiopyran-3-yl, 2H-thiopyran-4-yl, 2H-thiopyran-5-yl, and 2H-thiopyran-6-yl. The term “4H-thiopyranyl” as used herein includes 4H-thiopyran-2-yl, 4H-thiopyran-3-yl, and 4H-thiopyran-4-yl. The term “3,4-dihydro-2H-thiopyranyl” as used herein includes 3,4-dihydro-2H-thiopyran-2-yl, 3,4-dihydro-2H-thiopyran-3-yl, 3,4-dihydro-2H-thiopyran-4-yl, 3,4-dihydro-2H-thiopyran-5-yl, and 3,4-dihydro-2H-thiopyran-6-yl. The term “3,6-dihydro-2H-thiopyranyl” as used herein includes 3,6-dihydro-2H-thiopyran-2-yl, 3,6-dihydro-2H-thiopyran-3-yl, 3,6-dihydro-2H-thiopyran-4-yl, 3,6-dihydro-2H-thiopyran-5-yl and 3,6-dihydro-2H-thiopyran-6-yl. The term “piperazinyl” also known as “piperazidinyl” as used herein includes piperazin-1-yl and piperazin-2-yl. The term “morpholinyl” as used herein includes morpholin-2-yl, morpholin-3-yl, and morpholin-4-yl. The term “thiomorpholinyl” as used herein includes thiomorpholin-2-yl, thiomorpholin-3-yl and thiomorpholin-4-yl. The term “dioxanyl” as used herein includes 1,2-dioxan-3-yl, 1,2-dioxan-4-yl, 1,3-dioxan-2-yl, 1,3-dioxan-4-yl, 1,3-dioxan-5-yl, and 1,4-dioxan-2-yl. The term “dithianyl” as used herein includes 1,2-dithian-3-yl, 1,2-dithian-4-yl, 1,3-dithian-2-yl, 1,3-dithian-4-yl, 1,3-dithian-5-yl, and 1,4-dithian-2-yl. The term “oxathianyl” as used herein includes oxathian-2-yl and oxathian-3-yl. The term “trioxanyl” as used herein includes 1,2,3-trioxan-4-yl, 1,2,3-trioxan-5-yl, 1,2,4-trioxan-3-yl, 1,2,4-trioxan-5-yl, 1,2,4-trioxan-6-yl and 1,3,4-trioxan-2-yl. The term “azepanyl” as used herein includes azepan-1-yl, azepan-2-yl, azepan-3-yl, and azepan-4-yl. The term “homopiperazinyl” as used herein includes homopiperazin-1-yl, homopiperazin-2-yl, homopiperazin-3-yl, and homopiperazin-4-yl. The term “indolinyl” as used herein includes indolin-1-yl, indolin-2-yl, indolin-3-yl, indolin-4-yl, indolin-5-yl, indolin-6-yl, and indolin-7-yl. The term “quinolizinyl” as used herein includes quinolizidin-1-yl, quinolizidin-2-yl, quinolizidin-3-yl, and quinolizidin-4-yl. The term “isoindolinyl” as used herein includes isoindolin-1-yl, isoindolin-2-yl, isoindolin-3-yl, isoindolin-4-yl, isoindolin-5-yl, isoindolin-6-yl, and isoindolin-7-yl. The term “3H-indolyl” as used herein includes 3H-indol-2-yl, 3H-indol-3-yl, 3H-indol-4-yl, 3H-indol-5-yl, 3H-indol-6-yl, and 3H-indol-7-yl. The term “tetrahydroquinolinyl” as used herein includes tetrahydroquinolin-1-yl, tetrahydroquinolin-2-yl, tetrahydroquinolin-3-yl, tetrahydroquinolin-4-yl, tetrahydroquinolin-5-yl, tetrahydroquinolin-6-yl, tetrahydroquinolin-7-yl, and tetrahydroquinolin-8-yl. The term “tetrahydroisoquinolinyl” as used herein includes tetrahydroisoquinolin-1-yl, tetrahydroisoquinolin-2-yl, tetrahydroisoquinolin-3-yl, tetrahydroisoquinolin-4-yl, tetrahydroisoquinolin-5-yl, tetrahydroisoquinolin-6-yl, tetrahydroisoquinolin-7-yl, and tetrahydroisoquinolin-8-yl. The term “chromanyl” as used herein includes chroman-2-yl, chroman-3-yl, chroman-4-yl, chroman-5-yl, chroman-6-yl, chroman-7-yl, and chroman-8-yl. The term “1H-pyrrolizine” as used herein includes 1H-pyrrolizin-1-yl, 1H-pyrrolizin-2-yl, 1H-pyrrolizin-3-yl, 1H-pyrrolizin-5-yl, 1H-pyrrolizin-6-yl, and 1H-pyrrolizin-7-yl. The term “3H-pyrrolizine” as used herein includes 3H-pyrrolizin-1-yl, 3H-pyrrolizin-2-yl, 3H-pyrrolizin-3-yl, 3H-pyrrolizin-5-yl, 3H-pyrrolizin-6-yl, and 3H-pyrrolizin-7-yl.

The term “heteroaryl” as a group or part of a group, refers but is not limited to 5 to 12 carbon-atom aromatic rings or ring systems containing 1 or 2 rings which can be fused together or linked covalently, typically containing 5 to 6 atoms; at least one of which is aromatic in which one or more carbon atoms in one or more of these rings can be replaced by N, O, and/or S atoms where the N and S heteroatoms may optionally be oxidized and the N heteroatoms may optionally be quaternized, and wherein at least one carbon atom of said heteroaryl can be oxidized to form at least one C═O. Such rings may be fused to an aryl, cycloalkyl, heteroaryl or heterocyclyl ring. Non-limiting examples of such heteroaryl, include: pyrrolyl, furanyl, thiophenyl, pyrazolyl, imidazolyl, oxazolyl, isoxazolyl, thiazolyl, isothiazolyl, triazolyl, oxadiazolyl, thiadiazolyl, tetrazolyl, oxatriazolyl, thiatriazolyl, pyridinyl, pyrimidyl, pyrazinyl, pyridazinyl, oxazinyl, dioxinyl, thiazinyl, triazinyl, imidazo[2,1-b][1,3]thiazolyl, thieno[3,2-b]furanyl, thieno[3,2-b]thiophenyl, thieno[2,3-d][1,3]thiazolyl, thieno[2,3-d]imidazolyl, tetrazolo[1,5-a]pyridinyl, indolyl, indolizinyl, isoindolyl, benzofuranyl, isobenzofuranyl, benzothiophenyl, isobenzothiophenyl, indazolyl, benzimidazolyl, 1,3-benzoxazolyl, 1,2-benzisoxazolyl, 2,1-benzisoxazolyl, 1,3-benzothiazolyl, 1,2-benzoisothiazolyl, 2,1-benzoisothiazolyl, benzotriazolyl, 1,2,3-benzoxadiazolyl, 2,1,3-benzoxadiazolyl, 1,2,3-benzothiadiazolyl, 2,1,3-benzothiadiazolyl, benzo[d]oxazol-2(3H)-one, 2,3-dihydro-benzofuranyl, thienopyridinyl, purinyl, imidazo[1,2-a]pyridinyl, 6-oxo-pyridazin-1(6H)-yl, 2-oxopyridin-1(2H)-yl, 1,3-benzodioxolyl, quinolinyl, isoquinolinyl, cinnolinyl, quinazolinyl, quinoxalinyl; preferably said heteroaryl group is selected from the group consisting of pyridyl, 1,3-benzodioxolyl, benzo[d]oxazol-2(3H)-one, 2,3-dihydro-benzofuranyl, pyrazinyl, pyrazolyl, pyrrolyl, isoxazolyl, thiophenyl, imidazolyl, benzimidazolyl, pyrimidinyl, triazolyl, and thiazolyl.

The term “mono-, di- or tri-C₁₋₆alkylamino”, as a group or part of a group, refers to a group of formula —N(R^{o})(R^{p})(R^{q}) wherein R^{o}, R^{p}, and R^{q} are each independently selected from hydrogen, or C₁₋₆alkyl, wherein at least one of R^{o}, R^{p} or R^{q} is C₁₋₆alkyl. Thus, alkylamino groups include mono-alkyl amino group (e.g., mono-C₁₋₆alkylamino group such as methylamino and ethylamino), di-alkylamino group (e.g., di-C₁₋₆alkylamino group such as dimethylamino and diethylamino) and and tri-alkylamino group (e.g., tri-C₁₋₆alkylamino group such as trimethylamino and triethylamino). Non-limiting examples of suitable mono-, di-, and tri-C₁₋₆alkylamino groups include n-propylamino, isopropylamino, n-butylamino, i-butylamino, sec-butylamino, t-butylamino, pentylamino, n-hexylamino, di-n-propylamino, di-i-propylamino, ethylmethylamino, methyl-n-propylamino, methyl-1-propylamino, n-butylmethylamino, i-butylmethylamino, t-butylmethylamino, ethyl-n-propylamino, ethyl-1-propylamino, n-butylethylamino, i-butylethylamino, t-butylethylamino, di-n-butylamino, di-i-butylamino, methylpentylamino, methylhexylamino, ethylpentylamino, ethylhexylamino, propylpentylamino, propylhexylamino, tri-methylamino, tri-ethylamino, tri-n-propylamino, tri-isopropylamino, tri-n-butylamino, tri-i-butylamino, and the like.

In some embodiments, the apparatus may further comprise a reactant source constructed and arranged to provide a vapor of a reactant; wherein the precursor distribution and removal system is further configured to provide the vapor of the reactant from the reactant source to the reaction chamber; wherein the program stored in the memory is further configured to control the flow of the reactant from the reactant source to the reaction chamber during the one or more cycles.

In some embodiments, the one or more metal precursors and/or the one or more optional reactants are provided to the reaction chamber from a temperature-controlled vessel. In some embodiments, the temperature-controlled vessel is configured for cooling the precursor(s) and/or optional reactant(s).

In some embodiments the reactant is selected from the group comprising oxide reactants, nitride reactants, boride reactants, reducing agents, phosphide reactants, carbide reactants, sulfide reactants, and combinations thereof.

In some embodiments, the reactant is an oxide reactant, wherein the oxide reactant is selected from the group comprising H₂O, O₂, O₃, H₂O₂, N₂O, NO₂, N₂O₄, pyridine N-oxide, and O₂ plasma.

As used herein, an oxide reactant is a reagent that when put into contact with the metal precursor can produce a metal oxide.

In some embodiments, the reactant is a nitride reactant, wherein the nitride reactant is selected from the group comprising NH₃, N₂H₄, hydrazines, alkylamines, N₂ plasma, NH₃ plasma, and N₂/H₂ plasma.

As used herein, a nitride reactant is a reagent that when put into contact with the metal precursor can produce a metal nitride.

Suitable examples of hydrazines are compounds of formula

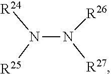

wherein R²⁴ is selected from the group comprising H, C₁₋₈alkyl, C₃₋₁₀cycloalkyl, and aryl; preferably R²⁴ is selected from the group comprising H, C₁₋₆alkyl, and aryl; preferably R²⁴ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl and naphthyl;

R²⁵ is selected from the group comprising H, C₁₋₈alkyl, C₃₋₁₀cycloalkyl, and aryl; preferably R²⁵ is selected from the group comprising H, C₁₋₆alkyl, and aryl; preferably R²⁵ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl, and naphthyl;

R²⁶ is selected from the group comprising H, C₁₋₈alkyl, C₃₋₁₀cycloalkyl and aryl; preferably R²⁶ is selected from the group comprising H, C₁₋₆alkyl, and aryl; preferably R²⁶ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl, and naphthyl;

R²⁷ is selected from the group comprising H, C₁₋₈alkyl, C₃₋₁₀cycloalkyl and aryl; preferably R²⁷ is selected from the group comprising H, C₁₋₆alkyl, and aryl; preferably R²⁷ is selected from the group comprising H, methyl, ethyl, n-propyl, iso-propyl, tert-butyl, n-butyl, iso-butyl, sec-butyl, n-pentyl, tert-pentyl, iso-pentyl, cyclopentyl, cyclohexyl, phenyl, and naphthyl.

Further non-limiting examples of suitable hydrazines include: tert-butyl-hydrazine, 1,1-dimethylhydrazine, methylhydrazine, and phenylhydrazine.

Suitable examples of alkylamines are compounds of formula

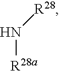

wherein R²⁸ is C₁₋₈alkyl; preferably R²⁸ is C₁₋₆alkyl; preferably R²⁸ is selected from the group comprising methyl, ethyl, n-propyl, iso-propyl, tert-butyl, n-butyl, iso-butyl, sec-butyl, n-pentyl, tert-pentyl, iso-pentyl, phenyl, and naphthyl.

R^{28a} is H or C₁₋₈alkyl; preferably R^{28a} is H or C₁₋₆alkyl; preferably R^{28a} is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl.

Further non-limiting examples of suitable alkylamines include: tert-butylamine, isobutylamine, tert-pentylamine.

In some embodiments, the reactant is a boride reactant, wherein the boride reactant is selected from the group comprising BF₃, BCl₃, BBr₃, BI₃, boranes, and compounds of formula

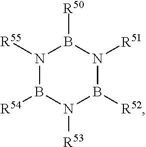

wherein
R⁵⁰ is selected from the group comprising halogen, C₁₋₈alkyl, and aryl; preferably R⁵⁰ is selected from the group comprising halogen, C₁₋₆alkyl, and aryl; preferably R⁵⁰ is selected from the group comprising halogen, C₁₋₄alkyl, and aryl; preferably R⁵⁰ is selected from the group comprising F, Cl, Br, I, C₁₋₆alkyl, and phenyl; preferably R⁵⁰ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵¹ is selected from the group comprising halogen, C₁₋₈alkyl, and aryl; preferably R⁵¹ is selected from the group comprising halogen, C₁₋₆alkyl, and aryl; preferably R⁵¹ is selected from the group comprising halogen, C₁₋₄alkyl, and aryl; preferably R⁵¹ is selected from the group comprising F, Cl, Br, I, C₁₋₆alkyl, and phenyl; preferably R⁵¹ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵² is selected from the group comprising halogen, C₁₋₈alkyl, and aryl; preferably R⁵² is selected from the group comprising halogen, C₁₋₆alkyl, and aryl; preferably R⁵² is selected from the group comprising halogen, C₁₋₄alkyl, and aryl; preferably R⁵² is selected from the group comprising F, Cl, Br, I, C₁₋₆alkyl, and phenyl; preferably R⁵² is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵³ is selected from the group comprising halogen, C₁₋₈alkyl, and aryl; preferably R⁵³ is selected from the group comprising halogen, C₁₋₆alkyl, and aryl; preferably R⁵³ is selected from the group comprising halogen, C₁₋₄alkyl, and aryl; preferably R⁵³ is selected from the group comprising F, Cl, Br, I, C₁₋₆alkyl, and phenyl; preferably R⁵³ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl;
R⁵⁴ is selected from the group comprising halogen, C₁₋₈alkyl, and aryl; preferably R⁵⁴ is selected from the group comprising halogen, C₁₋₆alkyl, and aryl; preferably R⁵⁴ is selected from the group comprising halogen, C₁₋₄alkyl, and aryl; preferably R⁵⁴ is selected from the group comprising F, Cl, Br, I, C₁₋₆alkyl, and phenyl; preferably R⁵⁴ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl and phenyl; and

R⁵⁵ is selected from the group comprising halogen, C₁₋₈alkyl, and aryl; preferably R⁵⁵ is selected from the group comprising halogen, C₁₋₆alkyl, and aryl; preferably R⁵⁵ is selected from the group comprising halogen, C₁₋₄alkyl, and aryl; preferably R⁵⁵ is selected from the group comprising F, Cl, Br, I, C₁₋₆alkyl, and phenyl; preferably R⁵⁵ is selected from the group comprising F, Cl, Br, I, methyl, ethyl, n-propyl, iso-propyl, tert-butyl, n-butyl, iso-butyl, sec-butyl, n-pentyl, tert-pentyl, iso-pentyl, and phenyl.

As used herein, a boride reactant is a reagent that when put into contact with the metal precursor can produce a metal boride.

Suitable examples of borazines are compounds such as borazine, trichloroborazine, tribromoborazine, 1,3,5-trimethylborazine.

Suitable examples of boranes are compounds selected from the group consisting of BH₃, B₂H₆, B₁₀H₁₄, B(CH₃)₃, B(CH₂CH₃)₃, B(OCH₃)₃, B[N(CH₃)₂]₃, pinacolborane, and compounds of formula R²⁹BH₃, wherein

R²⁹ is selected from the group comprising NH₃, mono-C₁₋₆alkylamino, di-C₁₋₆ alkylamino, tri-C₁₋₆alkylamino, —S(C₁₋₆alkyl)₂, heterocyclyl, heteroalkyl, and heteroaryl substituted with C₁₋₄alkyl; preferably R²⁹ is selected from the group comprising NH₃, mono-C₁. 4alkylamino, di-C₁₋₄alkylamino, tri-C₁₋₄alkylamino, —S(C₁₋₄alkyl)₂, heterocyclyl, heteroalkyl, and heteroaryl substituted with C₁₋₄alkyl; preferably R²⁹ is selected from the group comprising NH₃, trimethylamine, triethylamine, dimethylamine, diethylamine, di-tert-butylamine, methylamine, ethylamine, tert-butylamine, tetrahydrofuran, pyridine, 2-picoline.

Further non-limiting examples of suitable boranes include: BH₃[S(CH₃)₂], ammonia-borane, trimethylamine-borane, triethylamine-borane, pyridine-borane, dimethylamine-borane, 2-picoline-borane, tert-butylamine-borane, tetrahydrofuran-borane.

In some embodiments, the reactant is a reducing agent, wherein the reducing agent is selected from the group comprising H₂, H₂ plasma, N₂/H₂ plasma, N₂H₄, hydrazines, formic acid, formalin, boranes, SiH₄, Si₂H₆, H₂Si(SiH₃)₂, silanes, and cyclic dienes.

Suitable examples of hydrazines are compounds of formula

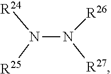

wherein R²⁴ is selected from the group comprising H, C₁₋₈alkyl, and aryl; preferably R²⁴ is selected from the group comprising H, C₁₋₆alkyl, and aryl; preferably R²⁴ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;

R²⁵ is selected from the group comprising H, C₁₋₈alkyl, and aryl; preferably R²⁵ is selected from the group comprising H, C₁₋₆alkyl, and aryl; preferably R²⁵ is selected from the group comprising H, methyl, ethyl, n-propyl, iso-propyl, tert-butyl, n-butyl, iso-butyl, sec-butyl, n-pentyl, tert-pentyl, iso-pentyl, phenyl and naphthyl;

R²⁶ is selected from the group comprising H, C₁₋₈alkyl, and aryl; preferably R²⁶ is selected from the group comprising H, C₁₋₆alkyl, and aryl; preferably R²⁶ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;

R²⁷ is selected from the group comprising H, C₁₋₈alkyl, and aryl; preferably R²⁷ is selected from the group comprising H, C₁₋₆alkyl, and aryl; preferably R²⁷ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl.

Suitable examples of boranes are compounds selected from the group consisting of BH₃, B₂H₆, B₁₀H₁₄, B(CH₃)₃, B(CH₂CH₃)₃, B(OCH₃)₃, B[N(CH₃)₂]₃, pinacolborane, and compounds of formula R²⁹BH₃, wherein

R²⁹ is selected from the group comprising NH₃, mono-C₁₋₆alkylamino, di-C₁₋₆ alkylamino, tri-C₁₋₆alkylamino, —S(C₁₋₆alkyl)₂, heterocyclyl, heteroalkyl, and heteroaryl substituted with C₁₋₄alkyl; preferably R²⁹ is selected from the group comprising NH₃, mono-aminoC₁₋₄alkyl, di-aminoC₁₋₄alkyl, tri-aminoC₁₋₄alkyl, —S(C₁₋₄alkyl)₂, heterocyclyl, heteroalkyl, and heteroaryl substituted with C₁₋₄alkyl; preferably R²⁹ is selected from the group comprising NH₃, trimethylamine, triethylamine, dimethylamine, diethylamine, di-tert-butylamine, methylamine, ethylamine, tert-butylamine, tetrahydrofuran, and pyridine, 2-picoline.

Further non-limiting examples of suitable boranes include: BH₃[S(CH₃)₂], ammonia-borane, trimethylamine-borane, triethylamine-borane, pyridine-borane, dimethylamine-borane, 2-picoline-borane, tert-butylamine-borane, and tetrahydrofuran-borane.

Suitable examples of silanes are compounds of formula

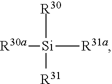

wherein R³⁰ is selected from the group comprising H, halogen, C₁₋₆alkyl, mono-C₁₋₆alkylamino, di-C₁₋₆ alkylamino, tri-Cl₁₋₆alkylamino and SiH₃; preferably R³⁰ is selected from the group comprising H, halogen, C₁₋₄alkyl mono-C₁₋₄alkylamino, di-C₁₋₄alkylamino, tri-C₁₋₄alkylamino, and SiH₃; preferably R³⁰ is selected from the group comprising H, F, Cl, Br, I, dimethylamino, diethylamino, diisopropylamino, di-tert-butylamino, methylamino, ethylamino, tert-butylamino, di-sec-butylamino, and SiH₃;

R^{30a} is selected from the group comprising H, halogen, C₁₋₆alkyl, mono-C₁₋₆alkylamino, di-C₁₋₆alkylamino, tri-C₁₋₆alkylamino, and SiH₃; preferably R^{30a} is selected from the group comprising H, halogen, C₁₋₄alkyl mono-C₁₋₄alkylamino, di-C₁₋₄alkylamino, tri-C₁₋₄alkylamino and SiH₃; preferably R^{30a} is selected from the group comprising H, F, Cl, Br, I, dimethylamino, diethylamino, diisopropylamino, di-tert-butylamino, methylamino, ethylamino tert-butylamino, di-sec-butylamino, and SiH₃;

R³¹ is selected from the group comprising H, halogen, C₁₋₆alkyl, mono-C₁₋₆alkylamino, di-C₁₋₆alkylamino, tri-C₁₋₆alkylamino and SiH₃; preferably R³¹ is selected from the group comprising H, halogen, C₁₋₄alkyl mono-C₁₋₄alkylamino, di-C₁₋₄alkylamino, tri-C₁₋₄alkylamino, and SiH₃; preferably R³¹ is selected from the group comprising H, F, Cl, Br, I, dimethylamino, diethylamino, diisopropylamino, di-tert-butylamino, methylamino, ethylamino, tert-butylamino di-sec-butylamino, and SiH₃; and

R^{31a} is selected from the group comprising H, halogen, C₁₋₆alkyl, mono-C₁₋₆alkylamino, di-C₁₋₆alkylamino, tri-C₁₋₆alkylamino and SiH₃; preferably R^{31a} is selected from the group comprising H, halogen, C₁₋₄alkyl mono-C₁₋₄alkylamino, di-C₁₋₄alkylamino, tri-C₁₋₄alkylamino and SiH₃; preferably R^{31a} is selected from the group comprising H, F, Cl, Br, I, dimethylamino, diethylamino, diisopropylamino, di-tert-butylamino, methylamino, ethylamino, tert-butylamino di-sec-butylamino, and SiH₃.

In some embodiments, at least two of R³⁰, R^{30a}, R³¹ or R^{31a} are H.

Suitable examples of silanes are compounds of formula SiₓH_{y}, wherein x is an integer selected from 1, 2, 3, 4, 5, or 6 and y is an integer selected from 0, 2x+2 or 2x. The skilled man in the art will appreciate that a silane of formula SiₓH_{y} includes, straight, branched, and cyclic silanes.

Further non-limiting examples of suitable silanes include: bis(diethylamino)silane, diisopropylaminosilane, silane, disilane, trisilane, cyclohexasilane, neopentasilane, and di-sec-butylaminosilane.

As used herein the term “cyclic diene” refers to a cyclic group having two double bonds, comprising from 3 to 12 carbon atoms, preferably from 3 to 9 carbon atoms, more preferably from 3 to 7 carbon atoms; more preferably from 3 to 6 carbon atoms; and which may have at least one heteroatom selected from N, O, and S, preferably at least one N atom. Cyclic dienes according to the invention may be substituted with one or more substituents selected from the group comprising C₁₋₆alkyl, halogen, C₁₋₆alkoxy, C₁₋₆alkylamino, di-C₁₋₆alkylamino, phenyl, and tri-C₁₋₆alkylsilyl. Further non-limiting examples of suitable cyclic dienes include: 1,3-cyclohexadiene, 1,4-cyclohexadiene, 1-methyl-1,4-cyclohexadiene, 1-methyl-1,3-cyclohexadiene, 2-methyl-1,3-cyclohexadiene, 3,6-bis(trimethylsilyl)-1,4-cyclohexadiene, 1-methyl-3,6-bis(trimethylsilyl)-1,4-cyclohexadiene, 9,10-dihydroanthracene, and 1,4-dihydro-1,4-bis(trimethylsilyl)pyrazine.

In some embodiments, the reactant is a phosphide reactant is selected from the group comprising phosphine, phosphorus halides, phosphorus oxyhalides, organophosphates, organophosphites, aminophosphines, alkylphosphines, and silylphosphines.

As used herein, a phosphide reactant is a reagent that when put into contact with the metal precursor can produce a metal phosphide.

Suitable examples of phosphorus halides include compounds of formula PX₃ or PX₅, wherein X is fluoro, chloro, bromo or iodo. Suitable but non limited examples of phosphorus halides include: e.g., phosphorus trichloride (PCl₃), phosphorus pentachloride (PCl₅), phosphorus tribromide (PBr₃), and phosphorus pentabromide (PBr₅).

Suitable examples of phosphorus oxyhalides include compounds of formula POX₃ wherein X is fluoro, chloro, bromo or iodo. Suitable but non limited examples of phosphorus oxyhalides include: e.g., phosphorus oxychloride (POCl₃), and phosphorus oxybromide (POBr₃)).

Suitable examples of organophosphates include compounds of formula

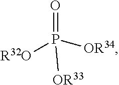

wherein
R³² is selected from the group comprising H, C₁₋₈alkyl, and aryl; preferably R³² is selected from the group comprising H, C₁₋₆alkyl, and aryl; preferably R³² is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
R³³ is selected from the group comprising H, C₁₋₈alkyl, and aryl; preferably R³³ is selected from the group comprising H, C₁₋₆alkyl, and aryl; preferably R³³ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
R³⁴ is selected from the group comprising H, C₁₋₈alkyl, and aryl; preferably R³⁴ is selected from the group comprising H, C₁₋₆alkyl, and aryl; preferably R³⁴ is selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl;
wherein only one of R³², R³³ or R³⁴ is hydrogen.

Suitable but non limited examples of organophosphates include trimethylphosphate (PO[OMe₃]), triethylphosphate (PO[OEt₃]).

Suitable examples of organophosphites include compounds of formula

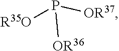

wherein
R³⁵ is selected from the group comprising H, C₁₋₈alkyl, —SiR^{35a} and aryl, wherein R^{35a} is C₁₋₆alkyl; preferably R³⁵ is selected from the group comprising H, C₁₋₆alkyl, —SiR^{35a} and aryl, wherein R^{35a} is C₁₋₆alkyl; preferably R³⁵ is selected from the group comprising H, methyl, ethyl, n-propyl, iso-propyl, tert-butyl, n-butyl, iso-butyl, sec-butyl, n-pentyl, tert-pentyl, iso-pentyl, trimethylsilyl, phenyl, and naphthyl;
R³⁶ is selected from the group comprising H, C₁₋₈alkyl, —SiR^{36a} and aryl, wherein R^{36a} is C₁₋₆alkyl; preferably R³⁶ is selected from the group comprising H, C₁₋₆alkyl, —SiR^{37a} and aryl, wherein R^{36a} is C₁₋₆alkyl; preferably R³⁶ is selected from the group comprising H, methyl, ethyl, n-propyl, iso-propyl, tert-butyl, n-butyl, iso-butyl, sec-butyl, n-pentyl, tert-pentyl, iso-pentyl, trimethylsilyl, phenyl, and naphthyl;
R³⁷ is selected from the group comprising H, C₁₋₈alkyl, —SiR^{37a} and aryl, wherein R^{37a} is C₁₋₆alkyl; preferably R³⁷ is selected from the group comprising H, C₁₋₆alkyl, —SiR^{37a} and aryl, wherein R^{37a} is C₁₋₆alkyl; preferably R³⁷ is selected from the group comprising H, methyl, ethyl, n-propyl, iso-propyl, tert-butyl, n-butyl, iso-butyl, sec-butyl, n-pentyl, tert-pentyl, iso-pentyl, trimethylsilyl, phenyl, and naphthyl;
wherein only one of R³⁵, R³⁶ or R³⁷ is hydrogen.

Suitable but non limited examples of organophosphites include trimethylphosphite (P[OMe]₃), triethylphosphite (P[OEt]₃).

Suitable examples of aminophosphines include compounds of formula

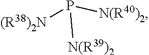

wherein
each R³⁸ is independently selected from the group comprising H, C₁₋₈alkyl, and aryl; preferably each R³⁸ is independently selected from the group comprising H, C₁₋₆alkyl and aryl; preferably each R³⁵ is independently selected from the group comprising H, methyl, ethyl, n-propyl, iso-propyl, tert-butyl, n-butyl, iso-butyl, sec-butyl, n-pentyl, tert-pentyl, iso-pentyl, phenyl and naphthyl;
each R³⁹ is independently selected from the group comprising H, C₁₋₈alkyl, and aryl; preferably each R³⁹ is independently selected from the group comprising H, C₁₋₆alkyl, and aryl; preferably each R³⁹ is independently selected from the group comprising H, methyl, ethyl, n-propyl, iso-propyl, tert-butyl, n-butyl, iso-butyl, sec-butyl, n-pentyl, tert-pentyl, iso-pentyl, phenyl and naphthyl;
each R⁴⁰ is independently selected from the group comprising H, C₁₋₈alkyl, and aryl; preferably each R⁴⁰ is independently selected from the group comprising H, C₁₋₆alkyl, and aryl; preferably each R⁴⁰ is independently selected from the group comprising H, methyl, ethyl, n-propyl, iso-propyl, tert-butyl, n-butyl, iso-butyl, sec-butyl, n-pentyl, tert-pentyl, iso-pentyl, phenyl, and naphthyl.

Suitable but non limited examples of aminophosphines include tris(dimethylamino)phosphine (P[NMe₂]₃), tris(ethylmethylamino)phosphine (P[NEtMe]₃), and tris(diethylamino)phosphine (P[NEt₂]₃).

Suitable examples of alkylphosphines include compounds of formula

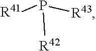

wherein
R⁴¹ is selected from H and C₁₋₈alkyl; preferably R⁴¹ is selected from H and C₁₋₆alkyl; preferably R⁴¹ is selected from H, methyl, ethyl, n-propyl, iso-propyl, tert-butyl, n-butyl, iso-butyl, sec-butyl, n-pentyl, tert-pentyl, and iso-pentyl;
R⁴² is selected from H and C₁₋₈alkyl; preferably R⁴² is selected from H and C₁₋₆alkyl; preferably R⁴² is selected from H, methyl, ethyl, n-propyl, iso-propyl, tert-butyl, n-butyl, iso-butyl, sec-butyl, n-pentyl, tert-pentyl, and iso-pentyl; and
R⁴³ is selected from H and C₁₋₈alkyl; preferably R⁴³ is selected from H and C₁₋₆alkyl; preferably R⁴³ is selected from H, methyl, ethyl, n-propyl, iso-propyl, tert-butyl, n-butyl, iso-butyl, sec-butyl, n-pentyl, tert-pentyl, and iso-pentyl;
wherein at least one of R⁴¹, R⁴² and R⁴³ is not hydrogen.

Suitable but non limited examples of alkylphosphines include tert-butyl phosphine (C₄H₉PH₂) and triethylphosphine (P[CH₂CH₃]₃).

Suitable examples of silylphosphines include compounds of formula

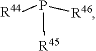

wherein
R⁴⁴ is H or Si(R^{44a})₃, wherein each R^{44a} is independently selected from the group comprising H, halogen, C₁₋₈alkyl, and aryl; preferably each R^{44a} is independently selected from the group comprising H, halogen, C₁₋₆alkyl and aryl; preferably each R^{44a} is independently selected from the group comprising H, F, Cl, Br, I, methyl, ethyl, n-propyl, iso-propyl, tert-butyl, n-butyl, iso-butyl, sec-butyl, n-pentyl, tert-pentyl, iso-pentyl, phenyl, and naphthyl;
R⁴⁵ is H or Si(R^{45a})₃, wherein each R^{45a} is independently selected from the group comprising H, halogen, C₁₋₈alkyl, and aryl; preferably each R^{45a} is independently selected from the group comprising H, halogen, C₁₋₆alkyl and aryl; preferably each R^{45a} is independently selected from the group comprising H, F, Cl, Br, I, methyl, ethyl, n-propyl, iso-propyl, tert-butyl, n-butyl, iso-butyl, sec-butyl, n-pentyl, tert-pentyl, iso-pentyl, phenyl, and naphthyl; and
R⁴⁶ is H or Si(R^{46a})₃, wherein each R^{46a} is independently selected from the group comprising H, halogen, C₁₋₈alkyl, and aryl; preferably each R^{46a} is independently selected from the group comprising H, halogen, C₁₋₆alkyl and aryl; preferably each R^{46a} is independently selected from the group comprising H, F, Cl, Br, I, methyl, ethyl, n-propyl, iso-propyl, tert-butyl, n-butyl, iso-butyl, sec-butyl, n-pentyl, tert-pentyl, iso-pentyl, phenyl and naphthyl;
wherein at least one of R⁴⁴, R⁴⁵, and R⁴⁶ is not H.

In some embodiments the silylphosphines include compounds of formula

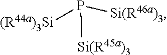

wherein each R^{44a}, R^{45a}, and R^{46a} are as defined hereinabove.

Suitable but non limited examples of silylphosphines include tris(trimethylsilyl)phosphine (P[SiMe₃]₃), and tri(silyl)phosphine (P[SiH₃]₃).

In some embodiments, the reactant is a reactant is a carbide reactant, wherein the carbide reactant is selected from the group comprising alkyl iodides, aryl iodides, alkyl bromides, aryl bromides, acetylene, propargyl chloride, propargyl bromide, propargyl iodide, allyl chloride, allyl bromide, allyl iodide, and cyclic dienes.

As used herein, a carbide reactant is a reagent that when put into contact with the metal precursor can produce a metal carbide.

As used herein the term “alkyl iodide” refers to a C₁₋₈alkyl group wherein one, two, or three hydrogen atoms are each replaced with an iodine atom; preferably C₁₋₆alkyl group; preferably a C₁₋₄alkyl group. Further non-limiting examples of suitable alkyl iodides include iodomethane, diiodomethane, iodoethane, 1,2-diiodoethane, and 1-iodobutane.

As used herein the term “aryl iodide” refers to an aryl group wherein one, two, three, four, five or six hydrogen atoms are each replaced with an iodine atom; preferably three hydrogen atoms; preferably two hydrogen atoms; preferably one hydrogen atom. Further non-limiting examples of suitable aryl iodides include iodobenzene, 1,2-diiodobenzene, 1,3-diiodobenzene, 1,4-diiodobenzene, 1,2,3-triiodobenzene, 1,2,4-triiodobenzene, 1,3,5-triiodobenzene, 1,2,3,4-tetraiodobenzene, 1,2,3,5-tetraiodobenzene, 1,2,4,5-tetraiodobenzene, and pentaidobenzene, hexaiodobenzene.

As used herein the term “alkyl bromide” refers to a C₁₋₈alkyl group wherein one, two, or three hydrogen atoms are each replaced with a bromine atom; preferably C₁₋₆alkyl group; preferably a C₁₋₄alkyl group.

As used herein the term “aryl bromide” refers to an aryl group wherein one, two, three, four, five or six hydrogen atoms are each replaced with a bromine atom; preferably three hydrogen atoms; preferably two hydrogen atoms; preferably one hydrogen atom.

Further non-limiting examples of suitable alkyl bromides include: bromoethane, 1,2-dibromoethane, and 1-bromobutane.

Further non-limiting examples of suitable aryl bromines include bromobenzene, 1,2-dibromobenzene, 1,3-dibromobenzene, 1,4-dibromobenzene, 1,2,3-tribromobenzene, 1,2,4-tribromobenzene, 1,3,5-tribromobenzene, 1,2,3,4-tetrabromobenzene, 1,2,3,5-tetrabromobenzene, 1,2,4,5-tetrabromobenzene, pentabromobenzene, and hexabromobenzene.

In some embodiments the reactant is a sulfide reactant, wherein the sulfide reactant is selected from the group comprising H₂S, Ss, S₂Cl₂, thiols, dithiols, bis(trimethylsilyl)sulfide, CS₂, and disulfides.

As used herein, a sulfide reactant is a reagent that when put into contact with the metal precursor can produce a metal sulfide.

Suitable examples of thiols include compounds of formula R⁴⁷SH, wherein
R⁴⁷ is selected from C₁₋₈alkyl, and aryl; preferably R⁴⁷ is selected from C₁₋₆alkyl, and aryl; preferably R⁴⁷ is selected from methyl, ethyl, n-propyl, iso-propyl, tert-butyl, n-butyl, iso-butyl, sec-butyl, n-pentyl, tert-pentyl, iso-pentyl, phenyl, and naphthyl.

Further non-limiting examples of suitable thiols include: tert-butyl thiol, 1-hexanethiol, tert-pentyl thiol, and thiophenol.

As used herein the term “dithiol” refers to a C₁₋₈alkyl group wherein two hydrogen atoms are replaced with thiol (—SH) group; preferably C₁₋₆alkyl group; preferably a C₁₋₄alkyl group. Further non-limiting examples of suitable dithiols include: 1,2-ethanedithiol, 1,3-propanedithiol, and 1,4-butanedithiol.

Suitable examples of disulfides include compounds of formula R⁴⁷—S—S—R⁴⁸, wherein
R⁴⁷ is selected from C₁₋₈alkyl, and aryl; preferably each R⁴⁷ is selected from C₁₋₆alkyl and aryl; preferably R⁴⁷ is selected from methyl, ethyl, n-propyl, iso-propyl, tert-butyl, n-butyl, iso-butyl, sec-butyl, n-pentyl, tert-pentyl, iso-pentyl, phenyl, and naphthyl; and
R⁴⁸ is selected from C₁₋₈alkyl, and aryl; preferably each R⁴⁸ is selected from C₁₋₆alkyl and aryl; preferably R⁴⁸ is selected from methyl, ethyl, n-propyl, iso-propyl, tert-butyl, n-butyl, iso-butyl, sec-butyl, n-pentyl, tert-pentyl, iso-pentyl, phenyl, and naphthyl.

Further non-limiting examples of suitable disulfides include: dimethyl disulfide, diethyl disulfide, and di-tert-butyl disulfide.

In some embodiments, the temperature-controlled vessel is configured for heating the precursors, and optional reactants. In some embodiments, the temperature controlled vessel is maintained at a temperature of at least −50° C. to at most 20° C., or at a temperature of at least 20° C. to at most 250° C., or at a temperature of at least 100° C. to at most 200° C.

In particular embodiments, the apparatus as disclosed herein may be configured to manufacture a semiconductor device as disclosed herein or a field-effect transistor (FET) as disclosed herein.

In particular embodiments, the apparatus as disclosed herein is configured for forming at least a portion of a semiconductor device as disclosed herein or a field-effect transistor (FET) as disclosed herein.

In some embodiments, the at least one metal precursor comprises:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu; preferably Cr, Mo, W, Sc, Y, La, Ce, Gd, Tb, Ho, Er, Ti, Zr, Hf, V, Nb, Ta, Co, Ni, Al, Ga, In, and Lu;
at least one ligand of formula (I)

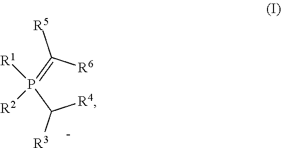

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.

In some embodiments the at least one metal precursor comprises at least one ligand of formula (I), wherein:
R¹ is selected from the group comprising C₁₋₆alkyl, C₃₋₆cycloalkyl, C₃₋₆cycloalkyl substituted with C₁₋₆alkyl, aryl, and aryl substituted with C₁₋₆alkyl; preferably R¹ is selected from the group comprising methyl, ethyl, n-propyl, iso-propyl, tert-butyl, n-butyl, iso-butyl, sec-butyl, C₃₋₆cycloalkyl, C₃₋₆cycloalkyl substituted with methyl, ethyl, n-propyl, n-butyl, sec-butyl or iso-butyl;
R² is selected from the group comprising C₁₋₆alkyl, C₃₋₆cycloalkyl, C₃₋₆cycloalkyl substituted with C₁₋₆alkyl, aryl, and aryl substituted with C₁₋₆alkyl; preferably R² is selected from the group comprising methyl, ethyl, n-propyl, iso-propyl, tert-butyl, n-butyl, iso-butyl, sec-butyl, C₃₋₆cycloalkyl, C₃₋₆cycloalkyl substituted with methyl, ethyl, n-propyl, n-butyl, sec-butyl or iso-butyl; or
R¹ and R² together with the phosphorus atom to which they are attached form a saturated or unsaturated 3-, 4-, 5-, 6-, 7-, 8-, 9-, or 10-membered ring; preferably R¹ and R² together with the phosphorus atom to which they are attached form a saturated or unsaturated 4-, 5-, 6-, 7- or 8-membered ring; preferably R¹ and R² together with the phosphorus atom to which they are attached form a saturated or unsaturated 5-, 6- or 7-membered ring;
R³ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl; preferably R³ is selected from the group comprising H, methyl, ethyl, n-propyl, iso-propyl, tert-butyl, n-butyl, iso-butyl, sec-butyl, C₃₋₆cycloalkyl, C₃₋₆cycloalkyl substituted with methyl, ethyl, n-propyl, n-butyl, sec-butyl or iso-butyl;
R⁴ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl; preferably R⁴ is selected from the group comprising H, methyl, ethyl, n-propyl, iso-propyl, tert-butyl, n-butyl, iso-butyl, sec-butyl, C₃₋₆cycloalkyl, C₃₋₆cycloalkyl substituted with methyl, ethyl, n-propyl, n-butyl, sec-butyl or iso-butyl;
R⁵ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl; preferably R⁵ is selected from the group comprising H, methyl, ethyl, n-propyl, iso-propyl, tert-butyl, n-butyl, iso-butyl, sec-butyl, C₃₋₆cycloalkyl, C₃₋₆cycloalkyl substituted with methyl, ethyl, n-propyl, n-butyl, sec-butyl or iso-butyl;
R⁶ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl; preferably R⁶ is selected from the group comprising H, methyl, ethyl, n-propyl, iso-propyl, tert-butyl, n-butyl, iso-butyl, sec-butyl, C₃₋₆cycloalkyl, C₃₋₆cycloalkyl substituted with methyl, ethyl, n-propyl, n-butyl, sec-butyl, or iso-butyl.

It should be understood that within the scope of the present disclosure the metal precursor may comprise any combination of the aforementioned types of ligands.

When forming the metal precursor of the present invention, the metal atom may interact with the ligand of formula (I) in two possible ways: in one way, the metal atom bonds with two carbon atoms of the ligand of formula (I), forming a bidentate ylide (see structures (A) and (B) below). Alternatively, the metal atom bonds with one carbon atom of the ligand of formula (I), forming a monodentate ylide (see structure (C) below).

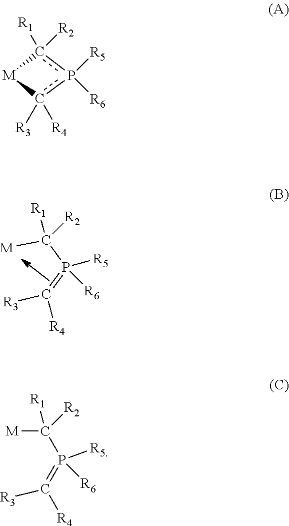

In some embodiments, the metal atom binds the ligand of formula (I) to form a bidentate ylide.

As used herein, a compound wherein identical ligands are linked to the same central metal atom are known in the art as homoleptic complex.

In some embodiments, the metal precursor comprises one or more identical ligands of formula (I); these compounds can also be referred to as homoleptic ylides. Some examples of homoleptic ylides according to the invention are:

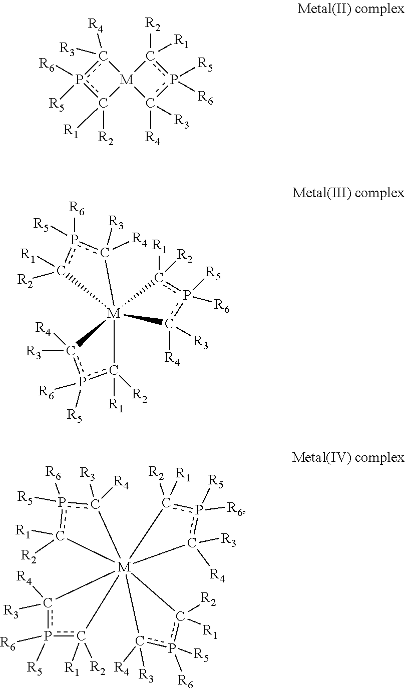

wherein
R¹, R², R³, R⁴, R⁵, and R⁶ are as described herein. Some non-limiting examples of homoleptic ylides according to the invention are:

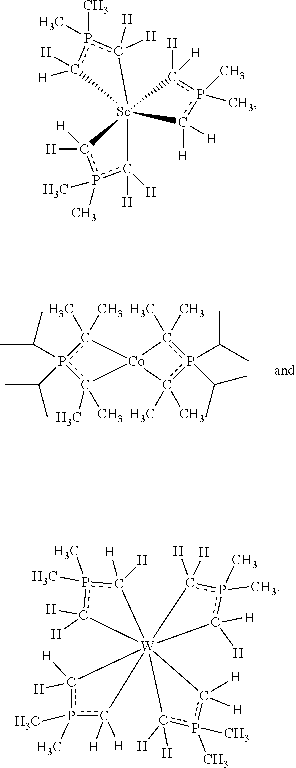

As used herein, a compound wherein different ligands are linked to the same central metal atom are known in the art as heteroleptic complexes.

In some embodiments, the metal precursor comprises at least one ligand of formula (I) and one or more further ligands selected from the group comprising cyclopendadienyl ligands, amide ligands, imido ligands, amidinate, halide ligands, alkyl ligands, alkoxide ligands, diketonate ligands and 1,4-diazabutadiene ligands.

In some embodiments, the one or more further ligand is a cyclopendadienyl ligand of formula (1)

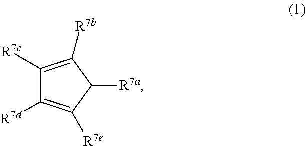

wherein
R^{7a} is selected from the group comprising H, C₁₋₈alkyl, and —SiR^{9a}, wherein R^{9a} is C₁₋₆ alkyl; preferably R^{7a} is selected from the group comprising H, C₁₋₆alkyl, and —SiR^{9a}, wherein R^{9a} is C₁₋₄alkyl; preferably R^{7a} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
R^{7b} is selected from the group comprising H, C₁₋₈alkyl, and —SiR^{9b}, wherein R^{9b} is C₁₋₆ alkyl; preferably R^{7b} is selected from the group comprising H, C₁₋₆alkyl, and —SiR^{9a}, wherein R^{9b} is C₁₋₄alkyl; preferably R^{7b} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;

R^{7c} is selected from the group comprising H, C₁₋₈alkyl, and —SiR^{9c}, wherein R^{9c} is C₁₋₆ alkyl; preferably R^{7c} is selected from the group comprising H, C₁₋₆alkyl, and —SiR^{9c}, wherein R^{9c} is C₁₋₄alkyl; preferably R^{7c} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;

R^{7d} is selected from the group comprising H, C₁₋₈alkyl, and —SiR^{9d}, wherein R^{9d} is C₁₋₆alkyl; preferably R^{7d} is selected from the group comprising H, C₁₋₆alkyl, and —SiR^{9d}, wherein R^{9d} is C₁₋₄alkyl; preferably R^{7d} is selected from the group comprising H, methyl, ethyl, n-propyl, iso-propyl, tert-butyl, n-butyl, iso-butyl, sec-butyl, n-pentyl, tert-pentyl, iso-pentyl, and trimethylsilyl; and

R^{7c} is selected from the group comprising H, C₁₋₈alkyl, and —SiR^{9e}, wherein R^{9e} is C₁₋₆ alkyl; preferably R^{7c} is selected from the group comprising H, C₁₋₆alkyl, and —SiR^{9e}, wherein R^{9e} is C₁₋₄alkyl; preferably R^{7c} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl.

In some embodiments, the cyclopentadienyl ligand is selected from the group comprising cyclopentadienyl, methylcyclopentadienyl, ethylcyclopentadienyl isopropylcyclopentadienyl, tert-butylcyclopentadienyl, trimethylsilylcyclopentadienyl, pentamethylcyclopentadienyl, 1,2,4-triisopropylcyclopentadienyl and 1,2,4-tri-tert-butylcyclopentadienyl.

In some embodiments, the cyclopentadienyl ligand binds to the metal in η-1, η-3, or η-5 coordination modes. The Greek letter eta (i) followed by a number indicates the number of contiguous atoms of the same type within a ligand are all simultaneously bonded to the metal atom. Preferably, the cyclopentadienyl ligand binds to the metal in i-5 coordination mode.

In some embodiments, the metal precursor comprises at least one ligand of formula (I) and one or more cyclopentadienyl ligands, wherein said metal precursor is of formula (II):

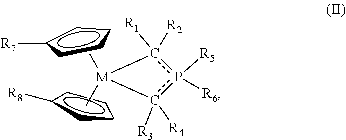

wherein R¹, R², R³, R⁴, R⁵ and R⁶ are as described herein;
R⁷ is selected from the group comprising H, C₁₋₈alkyl, and —SiR⁹, wherein R⁹ is C₁₋₆alkyl; preferably R⁷ is selected from the group comprising H, C₁₋₆alkyl, and —SiR⁹, wherein R⁹ is C₁₋₄alkyl; preferably R⁷ is selected from the group comprising H, methyl, ethyl, n-propyl, iso-propyl, tert-butyl, n-butyl, sec-butyl, iso-butyl, n-pentyl, tert-pentyl, iso-pentyl, and trimethylsilyl;
R⁸ is selected from the group comprising H, C₁₋₈alkyl, and —SiR¹⁰, wherein R¹⁰ is C₁₋₆alkyl; preferably R⁸ is selected from the group comprising H, C₁₋₆alkyl, and —SiR¹⁰, wherein R¹⁰ is C₁₋₄alkyl; preferably R⁸ is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl. In some of these embodiments, M is selected from Sc, Y, La, Ce, Pr, Nd, Pm, Sm, Eu, Gd, Tb, Dy, Ho, Er, Tm, and Yb, preferably from Sc, Y, La, and Ce.

In some embodiments, the one or more further ligand is an amido ligand of formula (2):

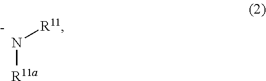

wherein
R¹¹ is independently selected from the group comprising H, C₁₋₈alkyl, and —SiR¹², wherein R¹² is C₁₋₆alkyl; preferably R¹¹ is selected from the group comprising H, C₁₋₆alkyl, and —SiR¹², wherein R¹² is C₁₋₄alkyl; preferably R¹¹ is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl; and
R^{11a} is independently selected from the group comprising H, C₁₋₈alkyl, and —SiR^{12a}, wherein R^{12a} is C₁₋₆alkyl; preferably R^{11a} is selected from the group comprising H, C₁₋₆alkyl, and —SiR^{12a}, wherein R^{12a} is C₁₋₄alkyl; preferably R^{11a} is selected from the group comprising H, methyl, ethyl, n-propyl, iso-propyl, tert-butyl, n-butyl, iso-butyl, sec-butyl, n-pentyl, tert-pentyl, iso-pentyl and trimethylsilyl;
wherein at least one of R¹¹ and R^{11a} is not H.

In some embodiments, the amido ligand is selected from the group comprising dimethylamido, diethylamido, ethylmethylamido, diisopropylamido, tert-butylamido, and bis(trimethylsilyl)amido.

In some embodiments, the one or more further ligand is an imido ligand of formula (3):

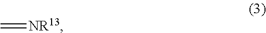

wherein
R¹³ is C₁₋₈alkyl; preferably R¹³ is C₁₋₆alkyl; preferably R¹³ is selected from the group comprising methyl, ethyl, n-propyl, iso-propyl, tert-butyl, n-butyl, iso-butyl, sec-butyl, n-pentyl, tert-pentyl, iso-pentyl and trimethylsilyl.

In some embodiments, the imido ligand is selected from the group comprising ethylimido, isopropylimido, isobutylimido, tert-butylimido, and tert-pentylimido.

In some embodiments, the metal precursor comprises at least one ligand of formula (I) and one or more imido ligands, wherein said metal precursor is of formula (III):

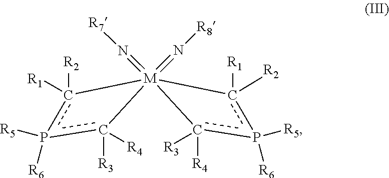

wherein R¹, R², R³, R⁴, R⁵ and R⁶ are as described herein;
R^{7′} is C₁₋₈alkyl; preferably R^{7′} is C₁₋₆alkyl; preferably R^{7′} is selected from the group comprising methyl, ethyl, n-propyl, iso-propyl, tert-butyl, n-butyl, iso-butyl, sec-butyl, n-pentyl, tert-pentyl and iso-pentyl; and

R^{8′} is C₁₋₈alkyl; preferably R^{8′} is C₁₋₆alkyl; preferably R^{8′} is selected from the group comprising methyl, ethyl, n-propyl, iso-propyl, tert-butyl, n-butyl, iso-butyl, sec-butyl, n-pentyl, tert-pentyl and iso-pentyl. In some of these embodiments, M is preferably selected from Cr, Mo, and W. In some embodiments, the one or more further ligand is an amidinate ligand of formula (4):

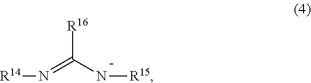

wherein
R¹⁴ is C₁₋₈alkyl; preferably R¹⁴ is C₁₋₆alkyl; preferably R¹⁴ is selected from the group comprising methyl, ethyl, n-propyl, iso-propyl, tert-butyl, n-butyl, iso-butyl, sec-butyl, n-pentyl, tert-pentyl, iso-pentyl;
R¹⁵ is C₁₋₈alkyl; preferably R¹⁵ is C₁₋₆alkyl; preferably R¹⁵ is selected from the group comprising methyl, ethyl, n-propyl, iso-propyl, tert-butyl, n-butyl, iso-butyl, sec-butyl, n-pentyl, tert-pentyl, and iso-pentyl; and
R¹⁶ is selected from the group comprising H, C₁₋₆alkyl, mono-C₁₋₆alkylamino, and di-C₁₋₆alkylamino; preferably R¹⁶ is selected from the group comprising H, C₁₋₄alkyl, mono-C₁₋₄alkylamino and di-C₁₋₄alkylamino; preferably R¹⁶ is selected from the group comprising H, methyl, ethyl, n-propyl, iso-propyl, tert-butyl, n-butyl, sec-butyl, iso-butyl, dimethylamine, diethylamine, and ethylmethylamine.

In some embodiments, the amidinate ligand is selected from the group comprising N,N′-diethylacetamidinate, N,N′-diisopropylacetamidinate, N,N′-diisopropylformamidinate, N,N′-di-tert-butylacetamidinate, and N,N′-di-tert-butylformamidinate.

In some embodiments, the one or more further ligand is an alkoxide ligand of formula (5):

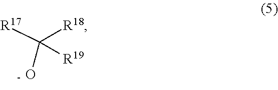

wherein
R¹⁷ is selected from the group comprising H, C₁₋₈alkyl, and aryl; preferably R¹⁷ is selected from H or C₁₋₆alkyl; preferably R¹⁷ is selected from the group comprising H, methyl, ethyl, n-propyl, iso-propyl, tert-butyl, n-butyl, iso-butyl, sec-butyl, n-pentyl, tert-pentyl, and iso-pentyl;
R¹⁸ is selected from the group comprising H, C₁₋₈alkyl, and aryl; preferably R¹⁸ is selected from H or C₁₋₆alkyl; preferably R¹⁸ is selected from the group comprising H, methyl, ethyl, n-propyl, iso-propyl, tert-butyl, n-butyl, iso-butyl, sec-butyl, n-pentyl, tert-pentyl, and iso-pentyl; and
R¹⁹ is selected from the group comprising H, C₁₋₈alkyl, and aryl; preferably R¹⁹ is selected from H or C₁₋₆alkyl; preferably R¹⁹ is selected from the group comprising H, methyl, ethyl, n-propyl, iso-propyl, tert-butyl, n-butyl, sec-butyl, iso-butyl, n-pentyl, tert-pentyl, and iso-pentyl.

In some embodiments the alkoxide ligand is selected from the group comprising methoxide, ethoxide, isopropoxide, tert-butoxide, 1-methoxy-2-methyl-2-propoxide, 1-dimethylamino-2-propoxide, 1-dimethylamino-2-methyl-2-propoxide, 1-ethylmethylamino-2-methyl-2-propoxide, 1-diethylamino-2-methyl-2-propoxide, 1-dimethylamino-2-methyl-2-butoxide, 1-ethylmethylamino-2-methyl-2-butoxide, and 1-diethylamino-2-methyl-2-butoxide.

In some embodiments, the one or more further ligand is a diketonate ligand of formula (6):

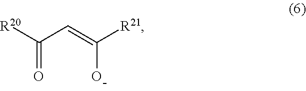

wherein
R²⁰ is selected from the group comprising C₁₋₈alkyl, C₁₋₈alkyl substituted with halogen, and aryl; preferably R²⁰ is selected from the group comprising C₁₋₆alkyl, C₁₋₆alkyl substituted with halogen and aryl; preferably R²⁰ is selected from the group comprising methyl, ethyl, n-propyl, iso-propyl, tert-butyl, n-butyl, iso-butyl, sec-butyl, n-pentyl, tert-pentyl, iso-pentyl, fluoromethyl, difluoromethyl, trifluoromethyl, chloromethyl, dichloromethyl, trichloromethyl, phenyl, and toluyl; and
R²¹ is selected from the group comprising C₁₋₈alkyl, C₁₋₈alkyl substituted with halogen and aryl; preferably R²¹ is selected from the group comprising C₁₋₆alkyl, C₁₋₆alkyl substituted with halogen and aryl; preferably R²¹ is selected from the group comprising methyl, ethyl, n-propyl, iso-propyl, tert-butyl, n-butyl, iso-butyl, sec-butyl, n-pentyl, tert-pentyl, iso-pentyl, fluoromethyl, difluoromethyl, trifluoromethyl, chloromethyl, dichloromethyl, trichloromethyl, phenyl, and toluyl.

In some embodiments, the diketonate ligand is selected from the group comprising acetylacetonate, 2,2,6,6-tetramethylheptane-3,5-dionate, and 1,1,1,5,5,5-hexafluoropentane-2,5-dionate.

In some embodiments, the one or more further ligand is a diazabutadiene ligand of formula (7):

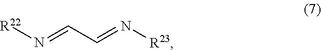

wherein
R²² is C₁₋₈alkyl; preferably R²² is C₁₋₆alkyl; preferably R²² is selected from the group comprising methyl, ethyl, n-propyl, iso-propyl, tert-butyl, n-butyl, iso-butyl, sec-butyl, n-pentyl, tert-pentyl, and iso-pentyl; and
R²³ is C₁₋₈alkyl; preferably R²³ is C₁₋₆alkyl; preferably R²³ is selected from the group comprising methyl, ethyl, n-propyl, iso-propyl, tert-butyl, n-butyl, iso-butyl, sec-butyl n-pentyl, tert-pentyl, and iso-pentyl.

In some embodiments, the diazabutadiene ligand is selected from the group comprising 1,4-di-tert-butyl-1,4-diaza-1,3-butadiene, 1,4-diisopropyl-1,4-diaza-1,3-butadiene, 1,4-di-sec-butyl-1,4-diaza-1,3-butadiene, and 1,4-di-tert-pentyl-1,4-diaza-1,3-butadiene.

Some non-limiting examples of heteroleptic ylides according to the invention are:

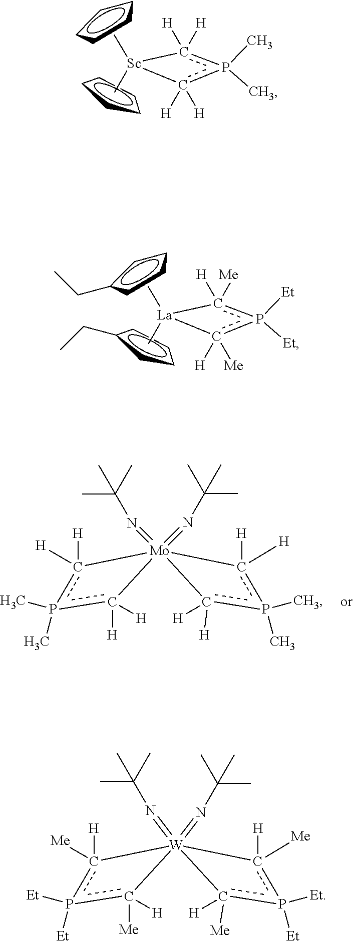

FIG. 2. schematically illustrates an apparatus (600) in accordance with yet additional exemplary embodiments of the disclosure. The apparatus (600) can be used to perform a method as described herein and/or form a (portion of) a transistor or semiconductor device as described herein.

In the illustrated example, the apparatus (600) includes one or more reaction chambers (602), a metal precursor gas source (604), a purge gas source (610), an exhaust (612), and a controller (614). The reaction chamber (602) can include any suitable reaction chamber, such as an ALD or CVD reaction chamber. Optionally, the apparatus (600) comprises further gas sources such as a reactant source (608) and a vacuum power source (611).

The metal gas source (604) is configured for delivering the metal precursor as described herein. The metal precursor gas source (604) can include a vessel and one or more metal precursors as described herein-alone or mixed with one or more carrier (e.g., inert) gases. The optional reactant source (608) can include a vessel and one or more reactants as described herein-alone or mixed with one or more carrier (e.g., inert) gases. The purge gas source (610) can include one or more inert gases such as N₂ or a noble gas, as described herein. The apparatus (600) can include any suitable number of gas sources. The gas sources (604)-(611) can be coupled to reaction chamber (602) via lines (616)-(621), which can each include flow controllers, valves, heaters, and the like. The exhaust (612) can include one or more vacuum pumps.

The controller (614) includes electronic circuitry and software to selectively operate valves, manifolds, heaters, pumps, and other components included in the apparatus (600). Such circuitry and components operate to introduce precursors, optional reactants, and purge gases from the respective sources (604)-(611). The controller (614) can control timing of gas pulse sequences, temperature of the substrate and/or reaction chamber, pressure within the reaction chamber, and various other operations to provide proper operation of the apparatus (600). The controller (614) can include control software to electrically or pneumatically control valves to control flow of precursors, optional reactants and purge gases into and out of the reaction chamber (602). The controller (614) can include modules such as a software or hardware component, e.g., a FPGA or ASIC, which performs certain tasks. A module can advantageously be configured to reside on the addressable storage medium of the control system and be configured to execute one or more processes.

Other configurations of the apparatus (600) are possible, including different numbers and kinds of precursor and optional reactant sources, and purge gas sources. Further, it will be appreciated that there are many arrangements of valves, conduits, precursor sources, optional reactant sources, and purge gas sources that may be used to accomplish the goal of selectively feeding gases into the reaction chamber (602). Further, as a schematic representation of an apparatus, many components have been omitted for simplicity of illustration, and such components may include, for example, various valves, manifolds, purifiers, heaters, containers, vents, and/or bypasses.

In addition, embodiments of the controller may include a combination of hardware, software, and electronic components or modules that, for purposes of discussion, may be portrayed as if primarily implemented in hardware. However, one of ordinary skill in the art, and based on a reading of this detailed description, would recognize that, in at least one embodiment, the electronic based aspects of the present disclosure may be implemented in software (e.g., instructions stored on non-transitory computer-readable medium) executable by one or more processing units, such as a microprocessor and/or application specific integrated circuits.

During operation of the reactor apparatus (600), substrates, such as semiconductor wafers (not illustrated), are transferred from, e.g., a substrate handling system to reaction chamber (602). Once substrate(s) are transferred to the reaction chamber (602), one or more gases from the gas sources (604)-(611), such as precursors, carrier gases, optional reactants, and/or purge gases, are introduced into reaction chamber (602).

Another aspect of the present disclosure relates to a method for forming a metal-containing layer on a semiconductor substrate, comprising the steps of:
a) providing a semiconductor substrate into a reaction chamber;
b) executing one or more cycles, each cycle comprising:
a metal precursor pulse, wherein at least a part of the semiconductor substrate is contacted by at least one metal precursor by introducing the at least one metal precursor into the reaction chamber;
wherein the at least one metal precursor comprises:
   at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
   at least one ligand of formula (I)

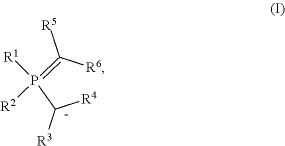

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl,
whereby, as a result of the cycles, the metal-containing layer is formed on the semiconductor substrate in the reaction chamber.

In accordance with step b) of the present method, and after providing the substrate to the reaction chamber, one or more (deposition) cycles are executed to form the metal-containing layer on the semiconductor substrate.

In particular, the present (deposition) method may be a cyclical deposition process, preferably a combination of cyclical deposition processes, such as an atomic layer deposition (ALD) process or a cyclical chemical vapor deposition (CVD) process. Each cyclical deposition process comprises one or more distinct (deposition) cycles. In particular embodiments, the method as disclosed herein may be an ALD method. In contrast to sputtering techniques commonly used within the state of the art for deposition of thin films and layers for the manufacturing of various semiconductors and transistors, cyclical deposition processes such as ALD were found to provide more uniform deposition across the surface of the substrate and/or (previously) deposited layers.

As used herein, the synonymous terms “deposition” or “cyclic deposition” or “cyclic deposition process” or “cyclical deposition process” refer to a sequential introduction of precursors (and/or reactants) into a reaction chamber to deposit a layer or film over a substrate and includes processing techniques such as ALD, CVD, and hybrid cyclical deposition processes that include an ALD component and a CVD component. Typically, one deposition cycle may form a film or layer of about 0.10 nm to about 0.2 nm. However, the experimental thickness may vary depending on the amount and type of cycles and available reaction sites on the substrate and/or a previously deposited layer.

The term “atomic layer deposition” (ALD) refers to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

In ALD processes, during each cycle, generally a precursor (e.g., a metal precursor) is introduced to a reaction chamber and is chemisorbed to a deposition surface (e.g., a substrate surface that can include a previously deposited material from a previous ALD cycle or other material), thereby forming a material, e.g., about a monolayer or sub-monolayer of material, or several monolayers of material, or a plurality of monolayers of material, which does not readily react with additional precursor (i.e., a self-limiting reaction). Thereafter, in some cases, a reactant (e.g., another precursor or reaction gas such as an oxygen reactant) may be introduced into the process chamber. The reactant can be capable of further reaction with the precursor. It should be noted that, as used herein, ALD processes are not necessarily comprised of a sequence of self-limiting surface reactions.

In some embodiments, step b) of the method according to the present disclosure further comprises a reactant pulse, wherein at least a part of the semiconductor substrate is contacted by at least one reactant, by introducing the at least one reactant into the reaction chamber. The description of the types of reactants provided under the apparatus section applies mutatis mutandis for the description of the method.

The description of the types of metal precursors and types of ligands provided under the apparatus section applies mutatis mutandis for the description of the method.

Optionally, purging steps can be utilized during one or more repetitions, e.g., during each deposition step, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gases that react with each other. For example, a purge, e.g., using an inert gas such as a noble gas, may be provided between subsequent pulses, thus avoiding or at least minimizing gas phase interactions between precursor(s) and/or reactant(s).

In particular embodiments, the method as disclosed herein provides that the reaction chamber is purged before and/or after each precursor pulse. In particular embodiments, the method as disclosed herein provides that the reaction chamber is purged before and/or after each metal precursor pulse and reactant pulse.

In some embodiments, the duration of the purge is greater than or equal to 0.1 second; preferably greater than or equal to 0.5 seconds; preferably greater than or equal to 1 second; preferably greater than or equal to 5 seconds; preferably greater than or equal to 10 seconds. In some embodiments, the duration is less than or equal to 60 seconds; preferably less than or equal to 45 seconds; preferably less than or equal to 35 seconds; preferably less than or equal to 20 seconds; preferably less than or equal to 10 seconds. In some embodiments, the duration o is from 0.1 to 60 seconds; preferably from 0.5 to 20 seconds; preferably from 5 to 10 seconds; preferably from 1 to 10 seconds.

Advantageously, a cyclical deposition process as disclosed herein can be a thermal deposition process. In other words, in some embodiments, none of the pulses or purges in the cyclical deposition process employs a plasma. In the case of thermal cyclical deposition processes, a duration of the step of providing the metal precursor to the reaction chamber, and/or a duration of the step of providing the reactant to the reaction chamber can be relatively long to allow the precursors and/or reactants to react with a surface of the substrate and/or a previously deposited layer.

In some embodiments, the duration of the step of providing the metal precursor to the reaction chamber is greater than or equal to 0.1 seconds; preferably greater than or equal to 0.5 seconds; preferably greater than or equal to 1 second; preferably greater than or equal to 5 seconds; preferably greater than or equal to 10 seconds. In some embodiments, the duration is less than or equal to 60 seconds; preferably less than or equal to 45 seconds; preferably less than or equal to 35 seconds; preferably less than or equal to 20 seconds; preferably less than or equal to 10 seconds. In some embodiments, the duration is from 0.1 to 60 seconds; preferably from 0.5 to 20 seconds; preferably from 5 to 10 seconds; preferably from I to 10 seconds.

In some embodiments, the duration of the step of providing the reactant to the reaction chamber is greater than or equal to 0.1 second; preferably greater than or equal to 0.5 seconds; preferably greater than or equal to 1 seconds; preferably greater than or equal to 5 seconds; preferably greater than or equal to 10 seconds. In some embodiments, the duration is less than or equal to 60 seconds; preferably less than or equal to 45 seconds; preferably less than or equal to 35 seconds; preferably less than or equal to 20 seconds; preferably less than or equal to 10 seconds. In some embodiments, the duration is from 0.1 to 60 seconds; preferably from 0.5 to 20 seconds; preferably from 5 to 10 seconds; preferably from 1 to 10 seconds.

In some embodiments, the cyclical deposition process employs a plasma-enhanced deposition technology. For example, the cyclical deposition process may comprise a plasma-enhanced atomic layer deposition process and/or a plasma-enhanced chemical vapor deposition process. In such a case, any one of the pulses in the cyclical deposition process may comprise generating a plasma in the reaction chamber.

In some embodiments, the method as disclosed herein may be a continuous vacuum deposition process. In the context of a continuous vacuum deposition process, a material is deposited onto a substrate in a reaction chamber without the introduction of atmospheric air or any interruptions that would break the controlled vacuum environment. This process involves maintaining a consistent vacuum pressure within the reaction chamber.

In particular embodiments, the method as disclosed herein provides that the metal-containing layer may be formed without any intervening vacuum break. The term “without any intervening vacuum break” can refer to without breaking a vacuum, without interruption as a timeline, without any material intervening step, without changing treatment conditions, and/or immediately thereafter.

In particular embodiments, the formation of the metal-containing layer may comprise at least 1 cycle, at least 2 cycles, at least 5 cycles, at least 10 cycles, at least 20 cycles, at least 40 cycles, at least 100 cycles, at least 200 cycles, at least 400 cycles, at least 600 cycles, at least 1000 cycles. In some embodiments, the steps may be repeated from at least 1 cycle to at most 5000 cycles; preferably from at least 1 cycle to at most 1000 cycles; preferably from at least 2 cycles to at most 100 cycles, preferably from at least 5 cycles to at most 50 cycles.

Each cycle may comprise one or more pulses. In some embodiments, at least one pulse involves a self-limiting surface reaction. In some embodiments, all pulses involve a self-limiting surface reaction. In the context of ALD, a self-limiting surface reaction refers to a chemical reaction that automatically halts or slows down once a certain threshold or coverage is reached on a surface, for instance, once a complete monolayer or sub-monolayer is formed the reaction stops by preventing further reaction with additional precursor. In some embodiments, a cycle comprises one or more precursor pulse(s), optionally one or more reactant pulse(s).

In particular embodiments, the metal-containing layer may have an average thickness of between 10.0 nm and 100.0 nm, or between 1.0 nm and 100.0 nm, or between 5.0 nm and 20 nm, or between 1.0 and 10.0 nm, or between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm. In particular embodiments, the method as disclosed herein provides that the channel layer may have an average thickness of between 0.05 nm and 2.0 nm, or between 0.10 nm and 2.0 nm, or between 0.10 nm and 1.75 nm, or between 0.10 nm and 1.50 nm, or between 0.10 nm and 1.25 nm, preferably between 0.10 nm and 1.0 nm, or between 0.20 nm and 1.0 nm, or between 0.25 nm and 1.0 nm.

In some embodiments, a cycle to grow a metal-containing layer may comprise the following sequence of pulses: a metal precursor pulse, and an optional reactant pulse. In the metal precursor pulse one or more metal precursor(s) is provided into the reaction chamber and may chemisorb to the substrate (i.e., adheres and forms chemical bonds with atoms or molecules on the surface of said substrate and/or a previously deposited layer or material). In the optional reactant pulse, one or more reactant(s) is provided into the reaction chamber and may react with the chemisorbed metal to form a metal-containing layer on at least a part of the substrate. The number of cycles determines the overall thickness of the deposited metal-containing layer.

An advantage of the presently disclosed cyclical deposition process(es) is the precise control over the overall layer thickness.

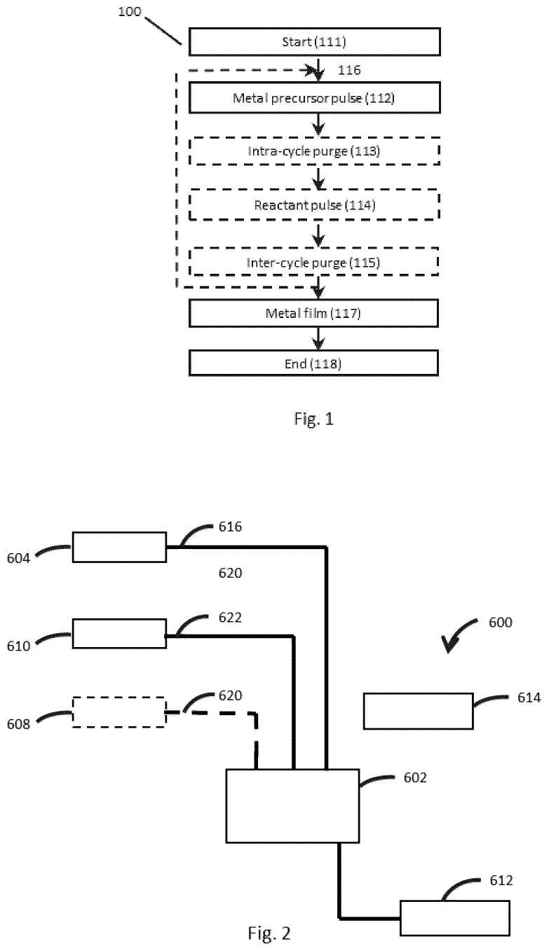

FIG. 1 describes an exemplary embodiment of the method (100) for forming a metal-containing layer on a semiconductor substrate as disclosed herein. The method starts (111) after a substrate has been provided to a reaction chamber. The cyclical deposition process comprises providing one or more metal precursors as described herein (gas) into the reaction chamber in a metal precursor pulse (112). Optionally, the reaction chamber is purged (113) after the metal precursor pulse (112). The metal precursor pulse is configured for delivering the metal precursor as described herein. Optionally, one or more reactants are provided to the reaction chamber in a reactant pulse (114). Optionally, the reaction chamber can be purged (115) after the reactant pulse.

The metal precursor pulse (112), the optional reactant pulse (114), and the optional purges (113,115) can be repeated (116) any number of times to obtain a metal-containing layer (117) having a desired thickness. When a metal-containing layer having a desired thickness has been deposited, the method concludes (118). Once the method has ended, the substrate can be subjected to additional processes known in the art for forming a device structure and/or device as disclosed herein (e.g., a FET).

It should be appreciated that the metal precursor pulse (112) and the optional reactant pulse (114) may overlap in a cycle. Further, the sequence of each method step (112 to 115) within each cycle may vary. For instance, and in another exemplary embodiment, a cycle may comprise the consecutive steps of an optional reactant pulse and a metal precursor pulse. Hence, an optional reactant pulse may precede a metal precursor pulse.

In particular embodiments, the method as disclosed herein provides that the metal precursor pulse and the optional reactant pulse comprise a plurality of micropulses. A “micropulse” as used herein is a short period during which one or more metal precursor(s) and optionally one or more reactant(s), may be introduced into the reaction chamber. Hence, the method as disclosed herein provides high flexibility in pulse sequence and length, thereby providing a cost-effective and more efficient method compared to conventional metal-containing layer production processes known in the art.

In some embodiments, the metal precursor pulse, and optionally one or more reactant(s) may last from at least 0.01s to at most 120 s, or from at least 0.01 s to at most 0.1 s, or from at least 0.01 s to at most 0.02 s, or from at least 0.02 s to at most 0.05 s, or from at least 0.05 s to at most 0.1 s, or from at least 0.1 s to at most 20 s, or from at least 0.1 s to at most 0.2 s, or from at least 0.2 s to at most 0.5 s, or from at least 0.5 s to at most 1.0 s, or from at least 1.0 s to at most 2.0 s, or from at least 2.0 s to at most 5.0 s, or from at least 5.0 s to at most 10.0 s, or from at least 10.0 s to at most 20.0 s.

It shall be understood that any two steps and/or pulses and/or micro pulses can be separated by a purge. Thus, in some embodiments, a metal precursor pulse and optionally a reactant pulse, may be separated by a purge. In some embodiments, subsequent cycles are separated by a purge.

In particular embodiments, the reaction chamber may be purged before and/or after a metal precursor pulse, and an optional reactant pulse. An advantage of purging is to prevent gas phase reactions that would prevent/eliminate self-limiting surface reactions. Another advantage of purging the reaction chamber before and/or after each precursor pulse and/or optional reactant pulse is that any residual precursor, reactant and/or reaction byproduct is removed, thereby avoiding cross-contamination between pulses and resulting in films or layers with high purity and less detrimental defects.

The method as disclosed herein may be performed at different temperatures and/or pressures. In particular embodiments, the method as disclosed herein provides that the substrate may be heated to a temperature of about 80° C. to about 500° C., or about 80° C. to about 400° C., or about 100° C. to about 400° C., or about 125° C. to about 400° C., preferably about 150° C. to about 400° C., or about 175° C. to about 400° C., preferably about 200° C. to about 400° C., or about 200° C. to about 300° C., or about 250° C. to about 400° C., or about 300° C. to about 400° C. The listed temperatures can decrease the time needed for material deposition, although lower or higher temperatures can be considered still.

In particular embodiments, the method as disclosed herein provides that the pressure in the reaction chamber is between about 0.1 Torr and about 100.0 Torr, or between about 0.5 Torr and about 100.0 Torr, or between about 1.0 Torr and about 100.0 Torr, or between about 2.0 Torr and about 100.0 Torr, or between about 5.0 Torr and about 100.0 Torr, or between about 5.0 Torr and about 80.0 Torr, or preferably between about 5.0 Torr and about 50.0 Torr, or between about 10.0 Torr and about 50.0 Torr, or between 0.5 and about 10.0 Torr. The listed pressures can decrease the time needed for material deposition, although lower or higher pressures can be considered still.

In some embodiments, the substrate is subjected to an annealing step in an ambient comprising hydrogen and nitrogen after the cyclical deposition process. Suitably, the annealing step can be carried out at a temperature from at least 300° C. to at most 600° C. Alternatively, the annealing step can be carried out at a temperature from at least 300° C. to at most 1000° C.

In some embodiments, the one or more metal precursors and/or the optional one or more reactant are provided to the reaction chamber by means of a carrier gas. Exemplary carrier gases include nitrogen (N₂) and a noble gas such as He, Ne, Ar, Xe, or Kr.

A continuous substrate may extend beyond the bounds of a process/reaction chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of a continuous substrate may include a sheet or a flexible material. Continuous substrates may also comprise carriers or sheets upon which non-continuous substrates are mounted.

Another aspect of the present disclosure relates to a semiconductor device structure formed according to the method described herein. The semiconductor device structure preferably comprises a metal-containing layer comprising a plurality of metal atoms selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu.

In some embodiments, the semiconductor device structure comprises a metal-containing layer comprising at least one ligand of formula (I):

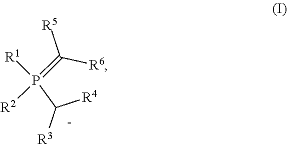

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.

Another aspect of the present disclosure relates to a composition configured for forming a metal containing film, the composition comprising at least one metal precursor comprising:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
at least one ligand of formula (I):

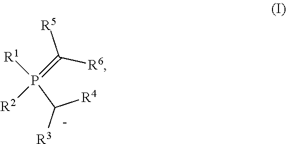

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.

Embodiments of the metal precursor are discussed above.

The composition disclosed herein may comprise one or more impurities. Use of the metal precursor for deposition requires a relatively high purity. Impurities in the composition are undesirable as they may degrade the quality of the resulting films. For instance, impurities in the composition may lead to impurity element incorporation in the resulting film. Additionally, or alternatively, impurities in the composition may lead to process drift due to differences in the vapor pressures of the various components of the composition. In some embodiments, the composition comprises at least about 95 wt % of the metal precursor, or at least about 97 wt % of the metal precursor, or at least about 98 wt % of the metal precursor, or at least about 99 wt % of the metal precursor, or at least about 99.5 wt % of the metal precursor, or at least about 99.7 wt % of the metal precursor, or at least about 99.9 wt % of the metal precursor, or at least about 99.99 wt % of the metal precursor.

In some embodiments, the composition is used to in the method described herein. In some embodiments, the composition is used in an apparatus as described herein.

Another aspect of the present disclosure relates to a vessel comprising a composition configured for forming a metal containing film, the composition comprising at least one metal precursor comprising:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
at least one ligand of formula (I):

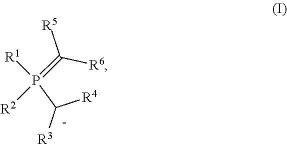

wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.

Embodiments of the metal precursor are discussed above.

The vessel is configured to store the composition and to provide a vapor flow of the composition from the vessel to an external environment, for example, to a substrate processing system or a semiconductor processing apparatus for forming a metal-containing film. The vessel is generally formed from a material that is non-reactive to the composition and, in some embodiments, may also be compliant with U.S. Department of Transportation (DOT) regulation, such as 49 C.F.R. § 178 (2021). In some embodiments, the vessel is formed from stainless steel (e.g., 316, 316L, 304, or 304L alloys). The configuration of the vessel may vary in different embodiments of the disclosure, depending upon the melting point and volatility of the metal precursor as well as other factors. The vessel, however, generally comprises an outer wall that encloses a cavity for storing the composition and a gas outlet for allowing a vapor of the composition to exit the cavity. The gas outlet is seated in the outer wall of the vessel and is in communication with the cavity of the vessel and has at least one valve positioned thereon to fluidly couple or decouple the cavity to the outside environment. In some embodiments, the vessel comprises one or more other fluid inlets or outlets, in addition to the gas outlet. For example, the vessel may comprise a fluid inlet that is seated in the outer wall of the vessel and is in communication with the cavity of the vessel and having at least one valve positioned thereon for filling the vessel with the composition. Additionally, or alternatively, the vessel may comprise a fluid inlet that is seated in the outer wall of the vessel and is in communication with the cavity of the vessel and having at least one valve positioned thereon for flowing a carrier gas into the cavity of the vessel, either over the surface of the composition and/or through the composition. Some or all of the one or more valves provided on the various inlets and outlets may be rated for high temperature (e.g., typically up to 100 C, or up to 150 C, or up to 200 C, or up to 250 C) to withstand the temperatures that may be required to provide sufficient vapor pressure and/or mitigate condensation or sticking of the composition within the values and other components.

In some embodiments, the vessel further comprises one or more probe members, that may comprise one or more temperature sensors, and/or one or more pressure sensors, and/or one or more level sensors or solid sensors. In these embodiments, the vessel may comprise a probe member port that is configured such that a probe member can be removably inserted into the cavity of the vessel. A variety of sensors for measuring the amount of the composition within the cavity of the vessel are known in the art, including, but not limited to, capacitive-based sensors, conductivity-based sensors, float switch level sensors, tuning fork sensors, and ultrasonic sensors.

In some embodiments, the vessel further comprises one or more heat transfer elements, such as, for example, fins, rods, beads, and the like, to facilitate heat transfer from the walls of the vessel to the composition within the cavity, or vice versa. The one or more heat transfer elements may comprise a series of pockets or compartments for holding the composition within the cavity. The one or more heat transfer elements may form a serpentine or radial path for holding the composition within the cavity and, in some cases, for directing the flow of a carrier gas over or through the composition. Such configurations are particularly useful for delivering a vapor of low-volatility liquids and solid compositions.

In some embodiments, the vessel is used to in the method described herein. In some embodiments, the vessel is used in an apparatus as described herein.

The subject matter of the present disclosure includes all novel and nonobvious combinations and sub-combinations of the various processes, apparatus, systems, and configurations, and other features, functions, acts, and/or properties disclosed herein, as well as any and all equivalents thereof.

The illustrations presented herein are not meant to be actual views of any particular material, structure, or device, but are merely idealized representations that are used to describe embodiments of the disclosure.

The particular implementations shown and described are illustrative of the disclosure and its best mode and are not intended to otherwise limit the scope of the aspects and implementations in any way. Indeed, for the sake of brevity, conventional manufacturing, connection, preparation, and other functional aspects of the apparatus may not be described in detail. Furthermore, the connecting lines shown in the various figures are intended to represent exemplary functional relationships and/or physical couplings between the various elements. Many alternative or additional functional relationships or physical connections may be present in the practical apparatus, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

1. An apparatus comprising:
a reaction chamber constructed and arranged to hold at least a semiconductor substrate;
a metal precursor source constructed and arranged to provide a vapor of at least one metal precursor;
a precursor distribution and removal system configured to provide the vapor of the metal precursor from the metal precursor source to the reaction chamber and to remove the vapor of the metal precursor from the reaction chamber; and
a sequence controller operably connected to the precursor distribution system and removal system, and comprising a memory provided with a program configured to control the flow of the metal precursor from the metal precursor source to the reaction chamber by activating the precursor distribution and removal system during one or more cycles; whereby, as a result of the cycles, a metal-containing layer is formed on the semiconductor substrate in the reaction chamber;
wherein the at least one metal precursor comprises:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
at least one ligand of formula (I): 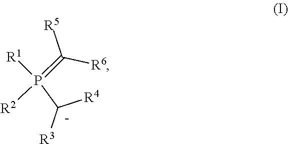
wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.

2. The apparatus according to claim 1, wherein
R¹ is selected from the group comprising C₁₋₆alkyl, C₃₋₆cycloalkyl, C₃₋₆cycloalkyl substituted with C₁₋₆alkyl, aryl, and aryl substituted with C₁₋₆alkyl;
R² is selected from the group comprising C₁₋₆alkyl, C₃₋₆cycloalkyl, C₃₋₆cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl;
R⁴ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl;
R⁵ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl; and
R⁶ is selected from the group comprising H, C₁₋₆alkyl, C₃₋₆cycloalkyl, C₃₋₆cycloalkyl substituted with C₁₋₆alkyl, aryl, and aryl substituted with C₁₋₆alkyl.

3. The apparatus according to claim 1, further comprising a reactant source constructed and arranged to provide a vapor of a reactant; wherein the precursor distribution and removal system is further configured to provide the vapor of the reactant from the reactant source to the reaction chamber; wherein the program stored in the memory is further configured to control the flow of the reactant from the reactant source to the reaction chamber during the one or more cycles.

4. The apparatus according to claim 3, wherein the reactant is selected from the group comprising oxide reactants, nitride reactants, boride reactants, reducing agents, phosphide reactants, carbide reactants, sulfide reactants and combinations thereof.

5. The apparatus according to claim 3, wherein the reactant is an oxide reactant, wherein the oxide reactant is selected from the group comprising H₂O, O₂, O₃, H₂O₂, N₂O, NO₂, N₂O₄, pyridine N-oxide and O₂ plasma.

6. The apparatus according to claim 3, wherein the reactant is a nitride reactant, wherein the nitride reactant is selected from the group comprising NH₃, N₂H₄, hydrazines, alkylamines, N₂ plasma, NH₃ plasma and N₂/H₂ plasma.

7. The apparatus according to claim 3, wherein the reactant is a boride reactant, wherein the boride reactant is selected from the group comprising borazines, BF₃, BCl₃, BBr₃, BI₃, and boranes.

8. The apparatus according to claim 3, wherein the reactant is a reducing agent, wherein the reducing agent is selected from the group comprising H₂, H₂ plasma, N₂/H₂ plasma, N₂H₄, hydrazines, formic acid, formalin, boranes, silanes, and cyclic dienes.

9. The apparatus according to claim 3, wherein the reactant is a phosphide reactant, wherein the phosphide reactant is selected from the group comprising phosphine, phosphorus halides, phosphorus oxyhalides, organophosphates, organophosphites, aminophosphines, alkylphosphines, and silylphosphines.

10. The apparatus according to claim 3, wherein the reactant is a carbide reactant, wherein the carbide reactant is selected from the group comprising alkyl iodides, iodobenzene, alkyl bromides bromobenzene, acetylene, propargyl chloride, propargyl bromide, propargyl iodide, allyl chloride, allyl bromide, allyl iodide, and cyclic dienes.

11. The apparatus according to claim 3, wherein the reactant is a sulfide reactant, wherein the sulfide reactant is selected from the group comprising H₂S, S₈, S₂Cl₂, thiols, dithiols, bis(trimethylsilyl)sulfide, CS₂ and disulfides.

12. The apparatus according to claim 1, wherein the at least one metal precursor further comprises one or more further ligands selected from the group comprising cyclopentadienyl ligands, amide ligands, imido ligands, amidinate ligands, halide ligands, alkyl ligands, alkoxide ligands, diketonate ligands and 1,4-diazabutadiene ligands.

13. The apparatus according to claim 1, wherein the at least one metal precursor further comprises one or more cyclopentadienyl ligand of formula (1): 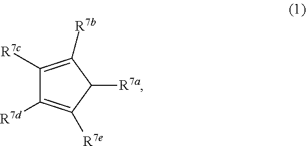
wherein
R^{7a} is selected from the group comprising H, C₁₋₈alkyl, and —SiR^{9a}, wherein R^{9a} is C₁₋₆alkyl;
R^{7b} is selected from the group comprising H, C₁₋₈alkyl, and —SiR^{9b}, wherein R^{9b} is C₁₋₆alkyl;
R^{7c} is selected from the group comprising H, C₁₋₈alkyl, and —SiR^{9c}, wherein R^{9c} is C₁₋₆alkyl;
R^{7d} is selected from the group comprising H, C₁₋₈alkyl, and —SiR^{9d}, wherein R^{9d} is C₁₋₆alkyl; and
R^{7c} is selected from the group comprising H, C₁₋₈alkyl, and —SiR^{9e}, wherein R^{9e} is C₁₋₆alkyl.

14. The apparatus according to claim 1, wherein the at least one metal precursor further comprises one or more amido ligands of formula (2): 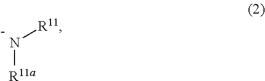
wherein
R¹¹ is independently selected from the group comprising H, C₁₋₈alkyl, and —SiR¹², wherein R¹² is C₁₋₆alkyl; and
R^{11a} is independently selected from the group comprising H, C₁₋₈alkyl, and —SiR^{12a}, wherein R^{12a} is C₁₋₆alkyl,
wherein at least one of R¹¹ and R^{11a} is not H.

15. The apparatus according to claim 1, wherein the at least one metal precursor only comprises ligands of formula (I).

16. A method for forming a metal-containing layer on a semiconductor substrate, comprising the steps of:
a) providing a semiconductor substrate into a reaction chamber; and
b) executing one or more cycles, each cycle comprising:
a metal precursor pulse, wherein at least a part of the semiconductor substrate is contacted by at least one metal precursor by introducing the at least one metal precursor into the reaction chamber;
wherein the at least one metal precursor comprises:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu;
at least one ligand of formula (I): 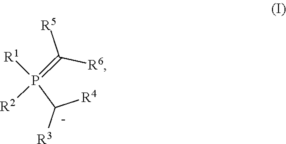
wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl,
whereby, as a result of the cycles, the metal-containing layer is formed on the semiconductor substrate in the reaction chamber.

17. The method according to claim 16, wherein the method comprises a cyclical deposition process that is part of an atomic layer deposition (ALD).

18. The method according to claim 16, wherein at least one cycle further comprises a reactant pulse, wherein at least a part of the semiconductor substrate is contacted by at least one reactant, by introducing the at least one reactant into the reaction chamber; wherein the at least one reactant is selected from the group comprising oxide reactants, nitride reactants, boride reactants, reducing agents, phosphide reactants, carbide reactants, sulfide reactants, and combinations thereof.

19. A semiconductor device structure comprising a metal-containing layer formed according to a method according to claim 16.

20. A composition configured for forming a metal containing film, the composition comprising at least one metal precursor comprising:
at least one metal selected from the group comprising Cr, Mo, W, Sc, Y, La, Ce, Pr, Nd, Pm, Sm, Eu, Gd, Tb, Dy, Ho, Er, Tm, Yb, Ti, Zr, Hf, V, Nb, Ta, Co, Ni, Al, Ga, In, Tl, and Lu; and
at least one ligand of formula (I): 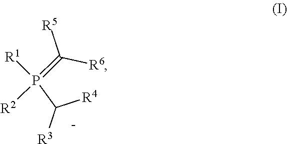
wherein,
R¹ is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl;
R² is selected from the group comprising C₁₋₁₀alkyl, C₃₋₁₀cycloalkyl, C₃₋₁₀cycloalkyl substituted with C₁₋₆alkyl, aryl, and aryl substituted with C₁₋₆alkyl; or
R¹ and R² together with the phosphorus atom to which they are attached form a saturated or unsaturated 3-, 4-, 5-, 6-, 7-, 8-, 9-, or 10-membered ring;
R³ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁴ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl;
R⁵ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl; and
R⁶ is selected from the group comprising H, C₁₋₁₀alkyl, C₃₋₁₀cycloalkyl, C₃₋₁₀cycloalkyl substituted with C₁₋₆alkyl, aryl, and aryl substituted with C₁₋₆alkyl.
